(19) United States
(12) Patent Application Publication
(10) Pub. No.: US 2026/0282395 A1
(43) Pub. Date: Sep. 17, 2026

(54) SEMICONDUCTOR DEVICE INCLUDING MEMORY CELLS AND PERIPHERAL CIRCUITS

(71) Applicant: Samsung Electronics Co., Ltd., Suwon-si (KR)

(72) Inventors: Jeonil Lee, Suwon-si (KR); Jinwoo Han, Suwon-si (KR)

(73) Assignee: Samsung Electronics Co., Ltd., Suwon-si (KR)

(21) Appl. No.: 19/566,939

(22) Filed: Mar. 13, 2026

(30) Foreign Application Priority Data
Mar. 17, 2025 (KR) 10-2025-0034106

(51) Int. Cl. H10B 80/00; G11C 11/408; G11C 11/4091; H10B 12/00; H10W 80/00; H10W 90/00; H10W 90/26

(52) U.S. Cl. CPC H10B 80/00; G11C 11/4085; G11C 11/4091; H10B 12/30; H10B 12/50; H10W 80/312; H10W 90/26; H10W 90/792

(57) ABSTRACT

A semiconductor device is provided. The semiconductor device includes a lower structure including lower word lines, lower local bit lines, and lower memory cells connected to the lower word lines and the lower local bit lines; an upper structure including upper word lines, upper local bit lines, and upper memory cells connected to the upper word lines and the upper local bit lines; and an intermediate structure disposed between the lower structure and the upper structure. The intermediate structure includes word line select circuits electrically connected to the lower word lines and the upper word lines; and sub-word line drivers electrically connected to the word line select circuits.

### CROSS-REFERENCE TO RELATED APPLICATIONS

This present application claims priority to and the benefit under 35 U.S.C. §119(a)(d) of Korean Patent Application No. 10-2025-0034106, filed on Mar. 17, 2025, in the Korean Intellectual Property Office, the entire disclosure of which is incorporated herein by reference.

### FIELD

Example embodiments of the present disclosure relate to a semiconductor device including memory cells and select circuits, and to a method of manufacturing a semiconductor device.

### BACKGROUND

Research has been conducted to reduce the sizes of elements included in a semiconductor device and to improve performance thereof. For example, in a DRAM, research to reliably and stably form elements having reduced sizes has been conducted, but as the sizes of elements are reduced, dispersion properties of a semiconductor device may be deteriorated.

### SUMMARY

Example embodiments provide a semiconductor device having increased integration density.

Example embodiments provide a method of manufacturing the semiconductor device.

According to example embodiments, a semiconductor device includes a lower structure including a lower bonding layer; an intermediate structure disposed on the lower structure and including a first intermediate bonding layer bonded to the lower bonding layer and a second intermediate bonding layer opposing the first intermediate bonding layer; and an upper structure disposed on the intermediate structure and including an upper bonding layer bonded to the second intermediate bonding layer, wherein the lower structure further includes lower memory cells arranged in a first direction, a second direction, and a vertical direction intersecting one another, wherein the intermediate structure further includes first peripheral circuits, wherein the upper structure further includes upper memory cells arranged in the first direction, the second direction, and the vertical direction, wherein each of the lower bonding layer and the first intermediate bonding layer includes a dielectric material and does not include a bonding metal material, wherein each of the second intermediate bonding layer and the upper bonding layer includes a bonding dielectric layer including a dielectric material and bonding metal patterns including a bonding metal material, wherein the bonding dielectric layer of the second intermediate bonding layer is bonded to the bonding dielectric layer of the upper bonding layer, and wherein the bonding metal patterns of the second intermediate bonding layer are bonded to the bonding metal patterns of the upper bonding layer. According to example embodiments, a semiconductor device includes a lower structure including lower word lines, lower local bit lines, and lower memory cells connected to the lower word lines and the lower local bit lines; an upper structure including upper word lines, upper local bit lines, and upper memory cells connected to the upper word lines and the upper local bit lines; and an intermediate structure disposed between the lower structure and the upper structure, and wherein the intermediate structure includes word line select circuits electrically connected to the lower word lines and the upper word lines; and sub-word line drivers electrically connected to the word line select circuits.

According to example embodiments, a semiconductor device includes a lower structure including a lower bonding layer; an intermediate structure disposed on the lower structure and including a first intermediate bonding layer bonded to the lower bonding layer and a second intermediate bonding layer opposing the first intermediate bonding layer; and an upper structure disposed on the intermediate structure and including an upper bonding layer bonded to the second intermediate bonding layer, wherein the lower structure further includes lower memory cells arranged in a first direction, a second direction, and a vertical direction intersecting one another; lower word lines connected to the lower memory cells; and lower local bit lines connected to the lower memory cells, wherein the intermediate structure further includes first peripheral circuits, wherein the upper structure further includes upper memory cells arranged in the first direction, the second direction, and the vertical direction; upper word lines connected to the upper memory cells; upper local bit lines connected to the upper memory cells; and second peripheral circuits disposed at a level higher than a level of the upper memory cells, wherein the first peripheral circuits include sub-word line select circuits electrically connected to the lower word lines and the upper word lines; and sub-word line drivers connected to the sub-word line select circuits.

### BRIEF DESCRIPTION OF THE DRAWINGS

The above and other aspects, features, and advantages of the present disclosure will be more clearly understood from the following detailed description, taken in combination with the accompanying drawings, in which:

FIGS. 1, 2A, 2B, 3A, and 3B are diagrams illustrating a semiconductor device according to example embodiments;

FIGS. 4A, 4B, 4C, 4D, 4E, and 5 are diagrams illustrating a semiconductor device according to example embodiments;

FIG. 6 is a cross-sectional diagram illustrating a semiconductor device according to example embodiments;

FIGS. 7, 8A and 8B are diagrams illustrating a semiconductor device according to example embodiments;

FIGS. 9, 10, and 11 are diagrams illustrating a semiconductor device according to example embodiments;

FIG. 12 is a diagram illustrating a semiconductor device according to example embodiments;

FIG. 13 is a diagram illustrating a semiconductor device according to example embodiments;

FIG. 14 is a diagram illustrating a semiconductor device according to example embodiments;

FIG. 15 is a diagram illustrating a semiconductor device according to example embodiments; and

FIGS. 16, 17, 18, 19A, 19B, 20A, 20B, 20C, and 21 are diagrams illustrating a method of manufacturing a semiconductor device according to example embodiments.

### DETAILED DESCRIPTION

Hereinafter, embodiments of the present disclosure will be described as follows with reference to the accompanying drawings.

Hereinafter, the terms such as “upper,” “intermediate” and “lower” may be replaced with other terms such as “first,” “second” and “third,” to describe elements in the example embodiments. The terms such as “first,” “second” and “third” may be used to describe various elements, but the elements are not limited by the terms, and a “first element” may be denoted as a “second element.” In the example embodiments, the terms such as “lower”, “upper”, “upper end”, and “lower end” may be described based on the drawings. The terms “lower”, “upper”, “upper end”, and “lower end” are described based on the drawings.

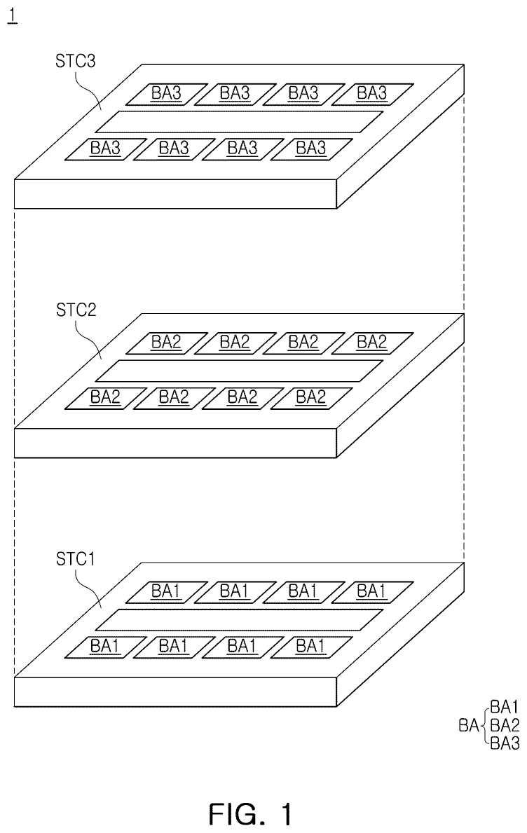

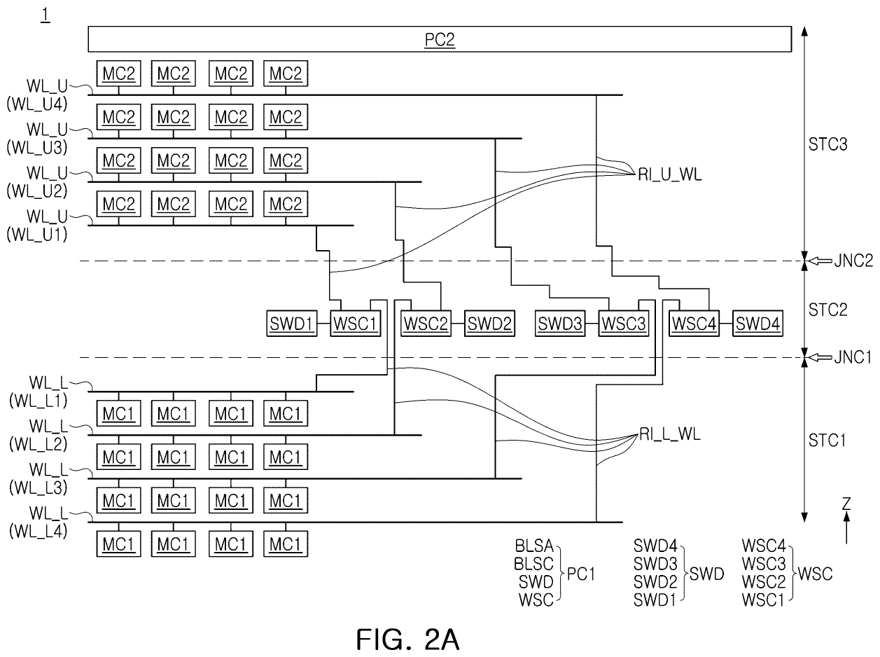

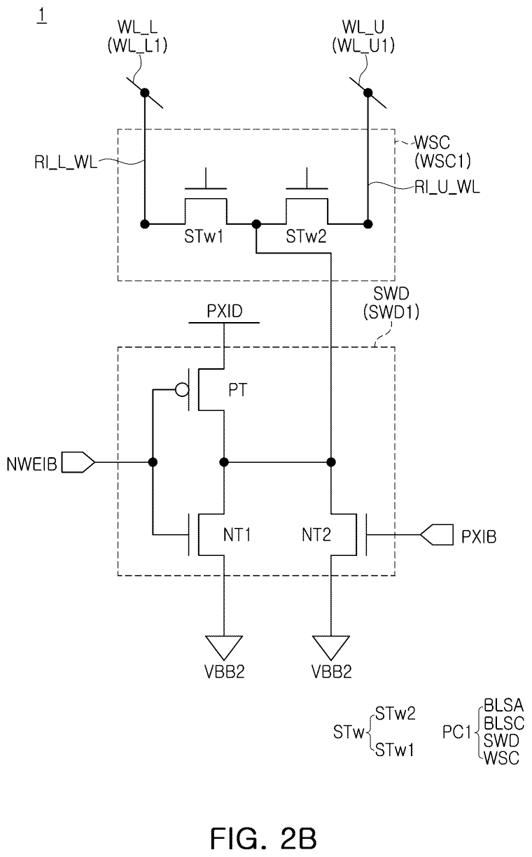

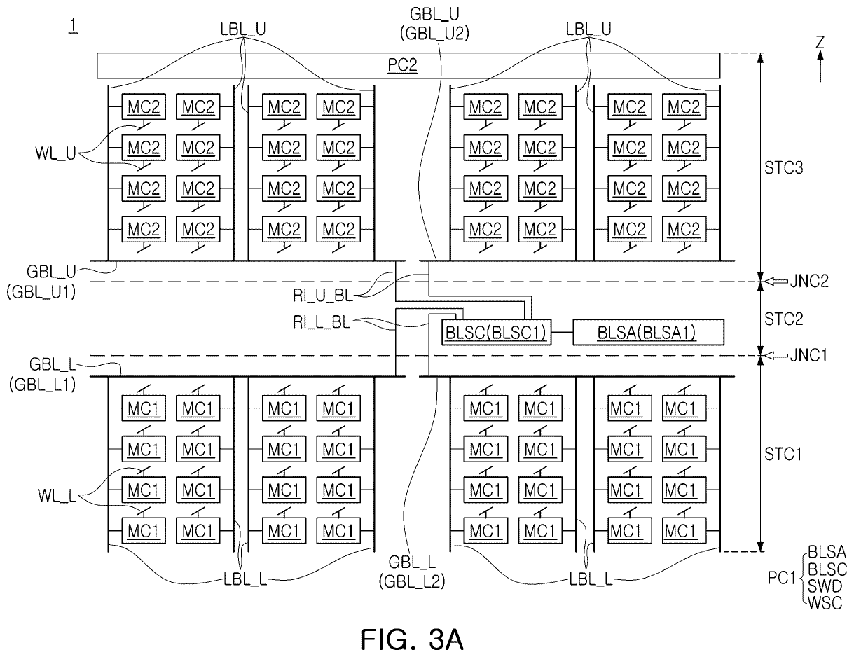

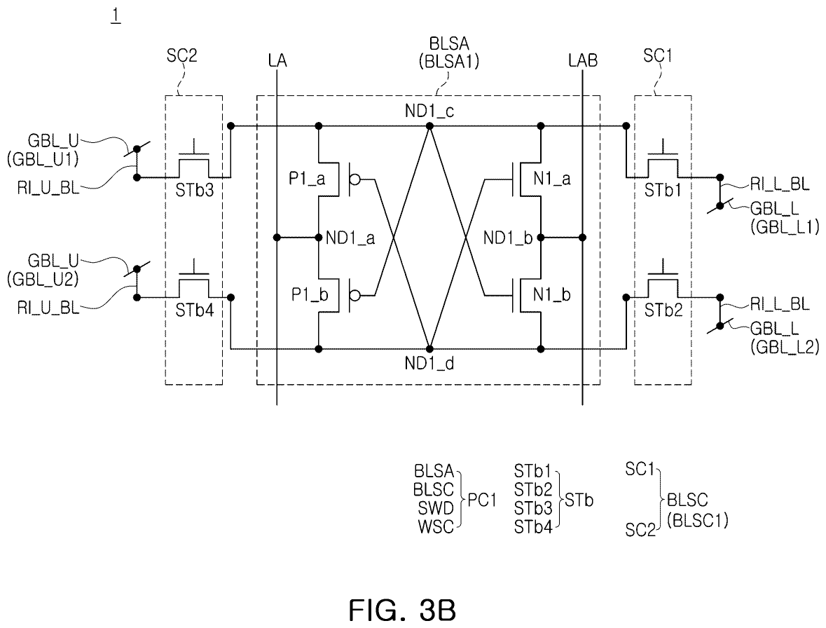

A semiconductor device according to example embodiments will be described with reference to FIGS. 1, 2A, 2B, 3A, and 3B. In FIGS. 1, 2A, 2B, 3A, and 3B, FIG. 1 is a perspective diagram illustrating a semiconductor device according to example embodiments, FIG. 2A is a diagram illustrating an arrangement relationship in a vertical direction of a semiconductor device according to example embodiments, FIG. 2B is a diagram including an example circuit of a semiconductor device according to example embodiments, FIG. 3A is a diagram illustrating an arrangement relationship in a vertical direction of a semiconductor device according to example embodiments, and FIG. 3B is a diagram including an example circuit of a semiconductor device according to example embodiments. FIGS. 2A and 2B are diagrams illustrating sub-word line drivers SWD and word line select circuits WSC, and FIGS. 3A and 3B are diagrams illustrating bit line sense amplifiers BLSA and bit line select circuits BLSC.

Referring to FIGS. 1, 2A, 2B, 3A, and 3B, a semiconductor device 1 according to example embodiments may include a lower structure STC1, an intermediate structure STC2 on the lower structure STC1, and an upper structure STC3 on the intermediate structure STC2. The lower structure STC1, the intermediate structure STC2, and the upper structure STC3 may be sequentially arranged in the vertical direction Z.

The lower structure STC1 and the intermediate structure STC2 may be bonded to one another and may form a first bonding region JNC1, and the intermediate structure STC2 and the upper structure STC3 may be bonded to one another and may form a second bonding region JNC2.

The semiconductor device 1 may include a plurality of banks BA. Each of the plurality of banks BA may include a first bank region BA1 in the lower structure STC1, a second bank region BA2 in the intermediate structure STC2, and a third bank region BA3 in the upper structure STC3.

The first bank region BA1 of the lower structure STC1 may include lower memory cells MC1 arranged three-dimensionally, and the third bank region BA3 of the upper structure STC3 may include upper memory cells MC2 arranged three-dimensionally. The second bank region BA2 of the intermediate structure STC2 may include first peripheral circuits PC1 for operating the lower memory cells MC1 and the upper memory cells MC2.

The lower structure STC1 may further include lower word lines WL_L connected to the lower memory cells MC1 and lower local bit lines LBL_L connected to the lower memory cells MC1.

The lower structure STC1 may further include lower global bit lines GBL_L electrically connected to the lower local bit lines LBL_L at a level higher than a level of the lower memory cells MC1 and the lower local bit lines LBL_L.

The upper structure STC3 may further include upper word lines WL_U connected to the upper memory cells MC2 and upper local bit lines LBL_U connected to the upper memory cells MC2.

The upper structure STC3 may further include upper global bit lines GBL_U electrically connected to the upper local bit lines LBL_U at a level lower than a level of the upper memory cells MC2 and the upper local bit lines LBL_U.

Each of the lower local bit lines LBL_L may be connected to the lower memory cells MC1 arranged in the vertical direction Z.

Each of the lower global bit lines GBL_L may be connected to an N number of lower local bit lines LBL_L among the lower local bit lines LBL_L. N may be a natural number of 2 or more.

Each of the upper local bit lines LBL_U may be connected to the upper memory cells MC2 arranged in the vertical direction Z.

Each of the upper global bit lines GBL_U may be connected to the N number of upper local bit lines LBL_U among the upper local bit lines LBL_U.

The lower word lines WL_L may include a first lower word line WL_L1, a second lower word line WL_L2, a third lower word line WL_L3, and a fourth lower word line WL_LA sequentially arranged in a direction away from the intermediate structure STC2.

The upper word lines WL_U may include a first upper word line WL_U1, a second upper word line WL_U2, a third upper word line WL_U3, and a fourth upper word line WL_U4 sequentially arranged in a direction away from the intermediate structure STC2.

The first peripheral circuits PC1 of the intermediate structure STC2 may include word line select circuits wsc and sub-word line drivers swd connected to the word line select circuits WSC.

The lower word lines WL_L may be electrically connected to the word line select circuits WSC by lower word line routing interconnection structures RI_L_WL. The upper word lines WL_U may be electrically connected to the word line select circuits WSC by upper word line routing interconnection structures RI_U_WL.

Each of the word line select circuits WSC may include a first word line select transistor STw1 electrically connected to a corresponding lower word line WL_L among the lower word lines WL_L and a second word line select transistor STw2 electrically connected to a corresponding upper word line WL_U among the upper word lines WL_U. The first word line select transistor STw1 and the second word line select transistor STw2 may be configured to operate in a complementary manner.

In example embodiments, when the first word line select transistor STw1 is in an on-state and the second word line select transistor STw2 is in an off-state, the lower word line WL_L may be connected to the sub-word line driver SWD, and the upper word line WL_U may be disconnected from the sub-word line driver SWD.

In example embodiments, when the first word line select transistor STw1 is in an off-state and the second word line select transistor STw2 is in an on-state, the lower word line WL_L may be disconnected from the sub-word line driver SWD, and the upper word line WL_U may be connected to the sub-word line driver SWD.

In example embodiments, one sub-word line driver SWD may be connected to a selected word line among the lower word line WL_L and the upper word line WL_U by one word line select circuit WSC connected to the sub-word line driver SWD.

The word line select circuits WSC may include a first word line select circuit WSC1, a second word line select circuit WSC2, a third word line select circuit WSC3, and a fourth word line select circuit WSC4.

The first word line select circuit WSC1 may be electrically connected to the first lower word line WL_L1 and the first upper word line WL_U1. The second word line select circuit WSC2 may be electrically connected to the second lower word line WL_L2 and the second upper word line WL_U2. The third word line select circuit WSC3 may be electrically connected to the third lower word line WL_L3 and the third upper word line WL_U3. The fourth word line select circuit WSC4 may be electrically connected to the fourth lower word line WL_L4 and the fourth upper word line WL_U4.

The sub-word line drivers SWD may include a first sub-word line driver SWD1 connected to the first word line select circuit WSC1, a second sub-word line driver SWD2 connected to the second word line select circuit WSC2, a third sub-word line driver SWD3 connected to the third word line select circuit WSC3, and a fourth sub-word line driver SWD4 connected to the fourth word line select circuit WSC4.

Each of the sub-word line drivers SWD may include a PMOS transistor PT, a first NMOS transistor NT1, and a second NMOS transistor NT2. A driving signal PXID may be connected to a source terminal of the PMOS transistor PT, a selected word line among the lower and upper word lines WL_L and WL_U may be electrically connected to a drain terminal of the PMOS transistor PT, and a word line enable signal NWEIB may be connected to a gate terminal of the PMOS transistor PT. The PMOS transistor PT may be a pull-up transistor. A precharge voltage corresponding to a back via voltage VBB2 may be connected to a source terminal of the first NMOS transistor NT1, a selected word line among the lower and upper word lines WL_L and WL_U may be electrically connected to a drain terminal of the first NMOS transistor NT1, and a word line enable signal NWEIB may be connected to a gate terminal of the first NMOS transistor NT1. The first NMOS transistor NT1 may be a pull-down transistor. A complementary driving signal PXIB may be connected to a gate terminal of the second NMOS transistor NT2, a precharge voltage corresponding to the back via voltage VBB2 may be connected to a source terminal of the second NMOS transistor NT2, and a selected word line among the lower and upper word lines WL_L and WL_U may be electrically connected to a drain terminal of the second NMOS transistor NT2.

The second NMOS transistor NT2 may be a keeping transistor for maintaining a selected word line among the lower and upper word lines WL_L and WL_U at a ground voltage level when the selected word line is not selected. The second NMOS transistor NT2 may be connected to the first NMOS transistor NT1 in parallel. Each of the sub-word line drivers SWD may drive a selected word line among the lower and upper word lines WL_L and WL_U in response to the word line enable signal NWEIB and the driving signal PXID. The PMOS transistor PT may pull-up a selected word line among the lower and upper word lines WL_L and WL_U to the level of the driving signal PXID in response to the word line enable signal NWEIB. The first NMOS transistor NT1 may pull down a selected word line among the lower and upper word lines WL_L and WL_U to the level of the negative voltage VBB2 in response to the word line enable signal NWEIB. The second NMOS transistor NT2, which may be a keeping transistor, may maintain a selected word line among the lower and upper word lines WL_L and WL_U to the level of the negative voltage VBB2 at the time point at which the selected word line among the lower and upper word lines WL_L and WL_U becomes inactive. To this end, the second NMOS transistor NT2 may switch between a source provided with the negative voltage VBB2 and a drain electrically connected to the selected word line among the lower and upper word lines WL_L and WL_U in response to the driving signal PXIB, which is complementary to the driving signal PXID.

The circuit of the sub-word line drivers SWD described above may be example embodiments, and the circuit of the sub-word line drivers SWD may be implemented as various circuit elements.

The first peripheral circuits PC1 of the intermediate structure STC2 may further include bit line select circuits BLSC and bit line sense amplifiers BLSA connected to the bit line select circuits BLSC.

The bit line select circuits BLSC may be electrically connected to the lower global bit lines GBL_L and the upper global bit lines GBL_U. The lower global bit lines GBL_L may be connected to the bit line select circuits BLSC by lower bit line routing interconnection structures RI_L_BL. The upper global bit lines GBL_U may be connected to the bit line select circuits BLSC by upper bit line routing interconnection structures RI_U_BL.

Each of the bit line sense amplifiers BLSA may be electrically connected to a pair of global bit lines selected by the bit line select circuit BLSC among the lower and upper global bit lines GBL_L, GBL_U connected to the bit line sense amplifier BLSA depending on operation of the corresponding bit line select circuit BLSC among the bit line select circuits BLSC, and may not be electrically connected to a pair of global bit lines unselected by the bit line select circuit BLSC.

Each of the bit line sense amplifiers BLSA may be connected to an M number of global bit lines among the lower and upper global bit lines GBL_L, GBL_U. In an example, “M” may be a natural number of 4 or more.

Each of the bit line sense amplifiers BLSA may include a plurality of sense amplifier transistors P1_a, P1_b, N1_a, and N1_b. The sense amplifier transistors P1_a, P1_b, N1_a, and N1_b may include a first PMOS transistor P1_a and a second PMOS transistor P1_b, a first NMOS transistor N1_a and the second NMOS transistor N1_b.

Each of the bit line select circuits BLSC may include select transistors STb.

Each of the bit line select circuits BLSC may include a first select circuit SC1 and a second select circuit SC2. In each of the bit line select circuits BLSC, the first select circuit SC1 may include a first lower select transistor STb1 connected to the first lower global bit line GBL_L1 among the lower global bit lines GBL_L, and a second lower select transistor STb2 connected to the second lower global bit line GBL_L2 among the lower global bit lines GBL_L.

In each of the bit line select circuits BLSC, the second select circuit SC2 may include a first upper select transistor STb3 connected to the first upper global bit line GBL_U1 among the upper global bit lines GBL_U and a second upper select transistor STb4 connected to the second upper global bit line GBL_U2 among the upper global bit lines GBL_U.

Hereinafter, the first bit line sense amplifier BLSA1 and the first bit line select circuit BLSC1, connected to one another, among the bit line sense amplifiers BLSA and the bit line select circuits BLSC will be described.

The first PMOS transistor P1_a and the second PMOS transistor P1_b may be referred to as a PMOS transistor pair, and the first NMOS transistor N1_a and the second NMOS transistor N1_b may be referred to as an NMOS transistor pair.

A source of the first PMOS transistor P1_a and a source of the second PMOS transistor P1_b may be connected to the first control line LA through the first node ND1_a. A source of the first NMOS transistor N1_a and a source of the second NMOS transistor N1_b may be connected to the second control line LAB through the second node ND1_b. The first node ND1_a and the second node ND1_b may be referred to as a first source node and a second source node, respectively.

Depending on operation of the first bit line select circuit BLSC1, a drain of the first PMOS transistor P1_a and a drain of the first NMOS transistor N1_a may be connected to one of the first lower global bit line GBL_L1, the second lower global bit line GBL_L2, the first upper global bit line GBL_U1, and the second upper global bit line GBL_U2 through the first drain node ND1_c.

Depending on operation of the first bit line select circuit BLSC1, a drain of the second PMOS transistor P1_b and a drain of the second NMOS transistor N1_b may be connected to one of the first lower global bit line GBL_L1, the second lower global bit line GBL_L2, the first upper global bit line GBL_U1, and the second upper global bit line GBL_U2, which may be a complementary bit line among the first lower global bit line GBL_L1, the second lower global bit line GBL_L2, the first upper global bit line GBL_U1, and the second upper global bit line GBL_U2 through a second drain node ND1_d.

In example embodiments, depending on operation of the first bit line select circuit BLSC1, the first bit line sense amplifier BLSA1 may be connected to a selected pair of global bit lines among the first lower global bit line GBL_L1, the second lower global bit line GBL_L2, the first upper global bit line GBL_U1, and the second upper global bit line GBL_U2, and may not be connected to a non-selected pair of global bit lines.

In example embodiments, depending on operation of the first bit line select circuit BLSC1, the first bit line sense amplifier BLSA1 may be connected to a pair of global bit lines of the first lower global bit line GBL_L1 and the second lower global bit line GBL_L2, and may not be connected to a pair of global bit lines of the first upper global bit line GBL_U1 and the second upper global bit line GBL_U2.

In example embodiments, depending on operation of the first bit line select circuit BLSC1, the first bit line sense amplifier BLSA1 may not be connected to a pair of global bit lines of the first lower global bit line GBL_L1 and the second lower global bit line GBL_L2, and may be connected to a pair of global bit lines of the first upper global bit line GBL_U1 and the second upper global bit line GBL_U2.

In example embodiments, depending on operation of the first bit line select circuit BLSC1, the first bit line sense amplifier BLSA1 may be connected to a pair of global bit lines of the first lower global bit line GBL_L1 and the first upper global bit line GBL_U1, and may not be connected to a pair of global bit lines of the second lower global bit line GBL_L2 and the second upper global bit line GBL_U2.

In example embodiments, depending on operation of the first bit line select circuit BLSC1, the first bit line sense amplifier BLSA1 may not be connected to a pair of global bit lines of the first lower global bit line GBL_L1 and the first upper global bit line GBL_U1, and may be connected to a pair of global bit lines of the second lower global bit line GBL_L2 and the second upper global bit line GBL_U2.

In example embodiments, the upper select transistors STb3 and STb4 and the lower select transistors STb1 and STb2 may be configured to operate in a complementary manner. For example, when the first upper select transistor STb3 and the second upper select transistor STb4 of the second select circuit SC2 are in an off-state and the first lower select transistor STb1 and the second lower select transistor STb2 of the first select circuit SC1 operate in an on-state, the first and second lower global bit lines GBL_L1 and GBL_L2 may be a pair of global bit lines selected by the first bit line select circuit BLSC1 and electrically connected to the first bit line sense amplifier BLSA1, and the first and second upper global bit lines GBL_U1 and GBL_U2 may be a pair of global bit lines unselected by the first bit line select circuit BLSC1 and electrically isolated from the first bit line sense amplifier BLSA1. For example, when the first upper select transistor STb3 and the second upper select transistor STb4 of the second select circuit SC2 are in an off-state, and the first lower select transistor STb1 and the second lower select transistor STb2 of the first select circuit SC1 operate in an on-state, a drain of the first PMOS transistor P1_a and a drain of the first NMOS transistor N1_a may be connected to the first lower global bit line GBL_L1 through the first drain node ND1_c, and a drain of the second PMOS transistor P1_b and a drain of the second NMOS transistor N1_b may be connected to the second lower global bit line GBL_L2, which may be a complementary bit line, through the second drain node ND1_d.

When the first upper select transistor STb3 and the second upper select transistor STb4 of the second select circuit SC2 are in an on-state and the first lower select transistor STb1 and the second lower select transistor STb2 of the first select circuit SC1 operate in an off-state, the first and second lower global bit lines GBL_L1 and GBL_L2 may be a pair of global bit lines unselected by the first bit line select circuit BLSC1 and electrically isolated from the first bit line sense amplifier BLSA1, and the first and second upper global bit lines GBL_U1 and GBL_U2 may be a pair of global bit lines selected by the first bit line select circuit BLSC1 and electrically connected to the first bit line sense amplifier BLSA1.

When the first bit line sense amplifier BLSA1 is electrically connected to the first and second lower global bit lines GBL_L1 and GBL_L2 by the first bit line select circuit BLSC1 and is not electrically connected to the first and second upper global bit lines GBL_U1 and GBL_U2 by the first bit line select circuit BLSC1, the first bit line sense amplifier BLSA1 may sense a voltage variation of the first lower global bit line GBL_1 and amplify the sensed voltage.

When the first bit line sense amplifier BLSA1 is not electrically connected to the first and second lower global bit lines GBL_L1 and GBL_L2 by the first bit line select circuit BLSC1, and is electrically connected to the first and second upper global bit lines GBL_U1 and GBL_U2 by the first bit line select circuit BLSC1, the first bit line sense amplifier BLSA1 may sense a voltage variation of the first upper global bit line GBL_U1 and amplify the sensed voltage.

When the first bit line sense amplifier BLSA1 performs a sensing and amplifying operation, an internal power voltage may be applied to the first node ND1_a through the first control line LA, and the second node ND1_b may be connected to a ground terminal through the second control line LAB. The first bit line sense amplifier BLSA1 may include a PMOS transistor pair and an NMOS transistor pair, and may be implemented as circuit elements in which transistors are cross-coupled to one another, but example embodiments thereof are not limited thereto. For example, the circuit of the first bit line sense amplifier BLSA1 may be implemented as various circuit elements.

The upper structure STC3 may further include second peripheral circuits PC2. The second peripheral circuits PC2 may include circuits for input/output of data or commands, or input of power/ground. The second peripheral circuits PC2 may be disposed at a level higher than a level of the upper memory cells MC2.

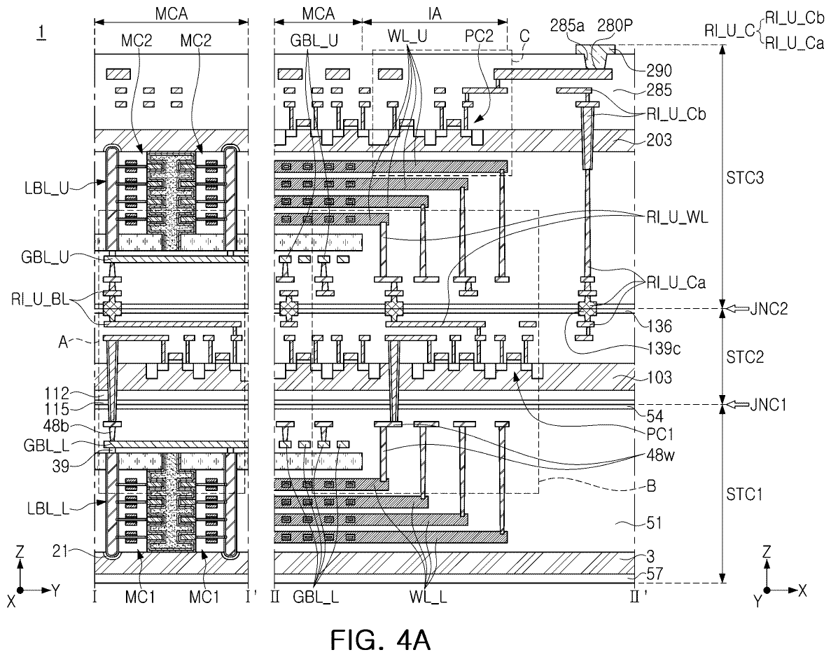

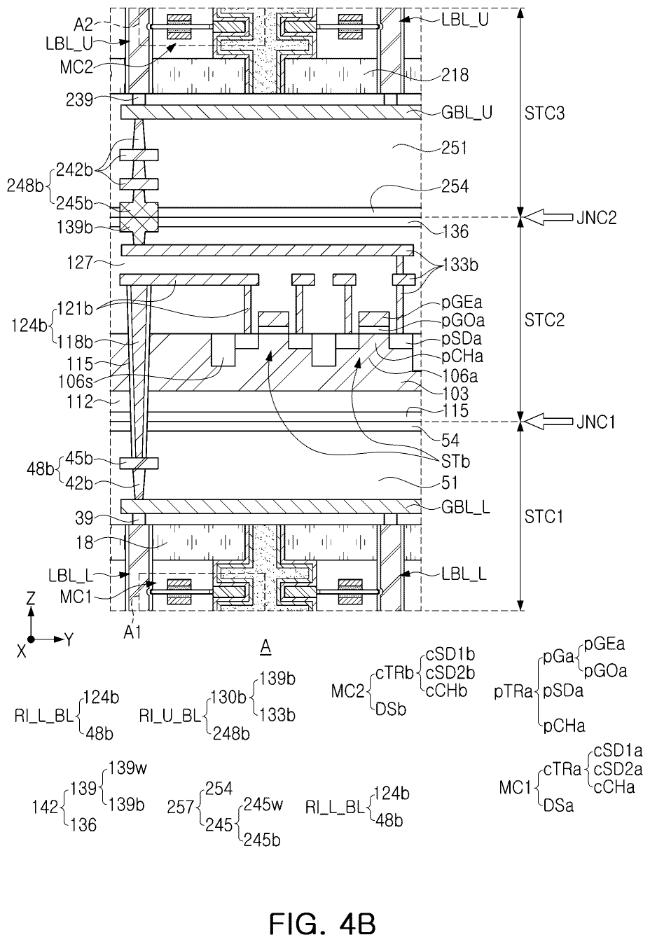

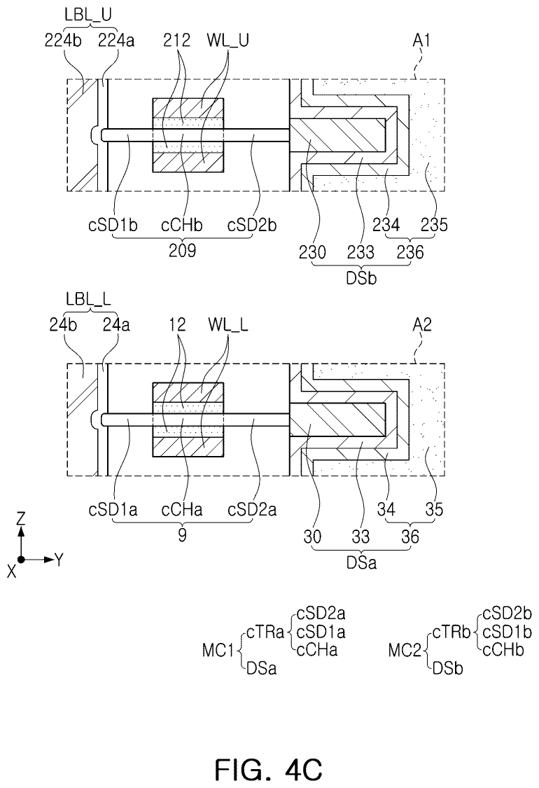

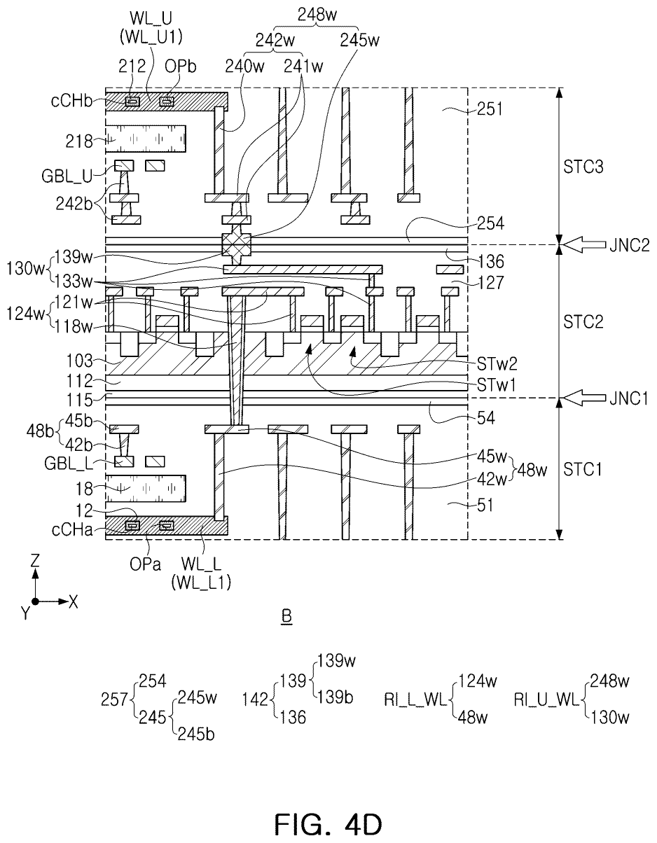

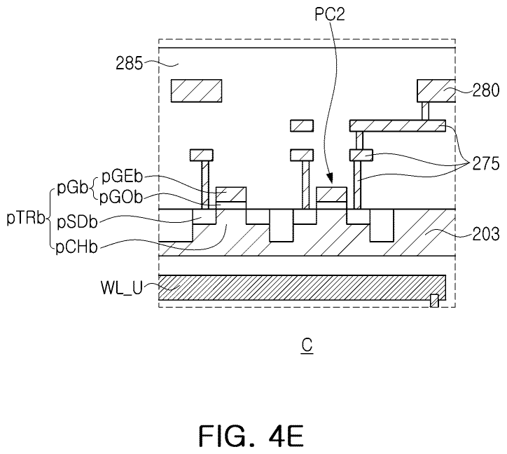

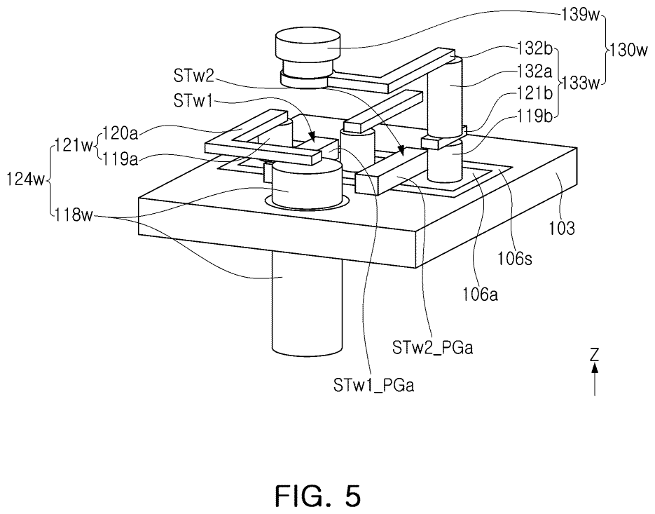

Example embodiments of the semiconductor device 1 described with reference to FIGS. 1, 2A, 2B, 3A, and 3B above will be described with reference to FIGS. 4A, 4B, 4C, 4D, 4E, and 5. As for FIGS. 4A, 4B, 4C, 4D, 4E, and FIG. 5, FIG. 4A is a cross-sectional diagram illustrating example embodiments of the semiconductor device 1 described above, FIG. 4B is an enlarged diagram illustrating region ‘A’ in FIG. 4A, FIG. 4C is an enlarged diagram illustrating regions ‘A1’ and ‘A2’ in FIG. 4A, FIG. 4D is an enlarged diagram illustrating region ‘B’ in FIG. 4A, FIG. 4E is an enlarged diagram illustrating region ‘C’ in FIG. 4A, and FIG. 5 is a perspective diagram illustrating a portion of elements of the intermediate structure STC2. In FIG. 4A, a cross-sectional structure taken along line I-I′ represents a region cut along a second direction Y, and a cross-sectional structure taken along line II-II′ represents a region cut in the first direction X perpendicular to the second direction Y.

Referring to FIGS. 1, 2A, 2B, 3A, and 3B, and also to FIGS. 4A, 4B, 4C, 4D, 4E, and 5, a semiconductor device 1 may include at least one memory cell array region MCA and a connection region IA adjacent to the at least one memory cell array region MCA.

The at least one memory cell array region MCA may be a region in which the lower memory cells MC1 and the upper memory cells MC2 are disposed. The lower word lines WL_L may be connected to the lower memory cells MC1 in the at least one memory cell array region MCA and may extend into the connection region IA.

The lower structure STC1 may further include a lower base 3 and a protective insulating layer 57 below the lower base 3. The lower base 3 may be a semiconductor substrate which may include a semiconductor material such as single crystal silicon, but example embodiments thereof are not limited thereto. For example, the lower base 3 may be an insulating substrate.

The intermediate structure STC2 may further include an intermediate semiconductor body 103. The intermediate semiconductor body 103 may include single crystal silicon.

The upper structure STC3 may further include an upper semiconductor body 203. The upper semiconductor body 203 may include single crystal silicon.

The lower memory cells MC1 may be disposed on the lower base 3. The lower memory cells MC1 may be arranged three-dimensionally in the first direction X, the second direction Y, and the vertical direction Z.

The first direction X and the second direction Y may be parallel to the upper surface of the lower base 3, and the vertical direction Z may be perpendicular to the upper surface of the lower base 3.

The first direction X may intersect the second direction Y. For example, the first direction X may be perpendicular to the second direction Y.

The upper memory cells MC2 may be disposed below the upper semiconductor body 203. The upper memory cells MC2 may be arranged three-dimensionally in the first direction X, the second direction Y, and the vertical direction Z.

Each of the lower memory cells MC1 may include a lower cell transistor cTRa and a lower data storage structure DSa. Each of the upper memory cells MC2 may include an upper cell transistor cTRb and an upper data storage structure DSb. The lower data storage structure DSa and the upper data storage structure DSb may be cell capacitors which may store data in a memory such as a DRAM.

Each of the lower cell transistors cTRa may include a lower channel region cCHa, first and second lower source/drain regions cSD1a and cSD2a, a lower gate dielectric layer 12, and a lower gate electrode WL_L. Here, the lower gate electrode WL_L may be the lower word line WL_L described above. Each of the upper cell transistors cTRb may include an upper channel region cCHb, first and second upper source/drain regions cSD1b and cSD2b, an upper gate dielectric layer 212, and an upper gate electrode WL_U. The upper gate electrode WL_U may be the upper word line WL_U described above.

In each of the lower cell transistors cTRa, the first lower source/drain region cSDla and the second lower source/drain region cSD2a may be spaced apart from one another in the second direction Y, the lower channel region cCHa may be disposed between the first lower source/drain region cSDla and the second lower source/drain region cSD2a, the lower gate electrode, that is, the lower word line WL_L, may vertically overlap the lower channel region cCHa, and the lower gate dielectric layer 12 may be disposed between the lower channel region cCHa and the lower word line WL_L. Each of the lower word lines WL_L may surround a corresponding lower channel region cCHa among the lower channel regions cCHa and may extend in the first direction X. Each of the lower word lines WL_L may have horizontal through-holes OPa. The lower channel regions cCHa and the lower gate dielectric layers 12 may be disposed in the horizontal through-holes OPa.

In each of the upper cell transistors cTRb, the first upper source/drain region cSD1b and the second upper source/drain region cSD2b may be spaced apart from one another in the second direction Y, the upper channel region cCHb may be disposed between the first upper source/drain region cSD1b and the second upper source/drain region cSD2b, the upper gate electrode, that is, the upper word line WL_U, may vertically overlap the upper channel region cCHb, and the upper gate dielectric layer 212 may be disposed between the upper channel region cCHb and the upper word line WL_U. Each of the upper word lines WL_U may surround a corresponding upper channel region cCHb among the upper channel regions cCHb and may extend in the first direction X. Each of the upper word lines WL_U may have horizontal through-holes OPb. The upper channel regions cCHb and the upper gate dielectric layers 212 may be disposed in the horizontal through-holes OPb.

Each of the lower data storage structures DSa may include a first lower electrode 30 connected to a corresponding second lower source/drain region cSD2a among the second lower source/drain regions cSD2a, a second lower electrode 36 covering the first lower electrode 30, and a lower dielectric layer 33 between the first lower electrode 30 and the second lower electrode 36. The second lower electrodes 36 may be lower plate electrodes.

Each of the upper data storage structures DSb may include a first upper electrode 230 connected to a corresponding second upper source/drain region cSD2b among the second upper source/drain regions cSD2b, a second upper electrode 236 covering the first upper electrode 230, and an upper dielectric layer 233 between the first upper electrode 230 and the second upper electrode 236. The second upper electrodes 236 may be upper plate electrodes.

In each of the lower data storage structures DSa, the first lower electrode 30 may have a columnar shape extending in the second direction Y, and the second lower electrode 36 may include a first electrode material layer 34 in contact with the lower dielectric layer 33 and a second electrode material layer 35 in contact with the first electrode material layer 34. In example embodiments, the first lower electrode 30 is not limited to a columnar shape. For example, the first lower electrode 30 may have a cylindrical shape. In each of the upper data storage structures DSb, the first upper electrode 230 may have a columnar shape extending in the second direction Y, and the second upper electrode 236 may include a first electrode material layer 234 in contact with the upper dielectric layer 233 and a second electrode material layer 235 in contact with the first electrode material layer 234. In example embodiments, the first upper electrode 230 is not limited to a columnar shape. For example, the first upper electrode 230 may having a cylindrical shape.

In the lower data storage structures DSa, a lower surface of each of the second lower electrodes 36 may be disposed at a level lower than a level of the lowermost cell transistor among the lower cell transistors cTRa, and an upper surface of each of the second lower electrodes 36 may be disposed at a level higher than a level of the uppermost cell transistor among the lower cell transistors cTRa. Each of the second lower electrodes 36 may extend in the first direction X. In the upper data storage structures DSb, an upper surface of each of the second upper electrodes 236 may be disposed at a level lower than a level of a lowermost cell transistor among the upper cell transistors cTRb, and an upper surface of each of the second upper electrodes 236 may be disposed at a level higher than a level of an uppermost cell transistor among the upper cell transistors cTRb. Each of the second upper electrodes 236 may extend in the first direction X.

The lower structure STC1 may further include lower active patterns 9. The upper structure STC3 may further include upper active patterns 209.

The lower and upper active patterns 9 and 209 may be formed of a semiconductor material which may be used as a channel region of a transistor. For example, each of the lower and upper active patterns 9 and 209 may include a single crystal silicon semiconductor, an oxide semiconductor, or a two-dimensional material having semiconductor properties. Each of the lower and upper active patterns 9 and 209 may have a bar shape extending in the second direction Y.

The first and second lower source/drain regions cSD1a and cSD2a, and the lower channel regions cCHa may be disposed in the lower active patterns 9. For example, each of the lower active patterns 9 may include the first lower source/drain region cSDla and the second lower source/drain region cSD2a spaced apart from one another in the second direction Y, and the lower channel region cCHa between the first and second lower source/drain regions cSD1a and cSD2a.

The first and second upper source/drain regions cSD1b and cSD2b, and the upper channel regions cCHb may be disposed in the upper active patterns 209. For example, each of the upper active patterns 209 may include the first upper source/drain region cSD1b and the second upper source/drain region cSD2b spaced apart from one another in the second direction Y, and the upper channel region cCHb between the first and second upper source/drain regions cSD1b and cSD2b.

Each of the lower local bit lines LBL_L may have a columnar shape extending in the vertical direction Z. The lower local bit lines LBL_L may be arranged in the first direction X and the second direction Y. Each of the upper local bit lines LBL_U may have a columnar shape extending in the vertical direction Z. The upper local bit lines LBL_U may be arranged in the first direction X and the second direction Y.

The lower local bit lines LBL_L may vertically overlap the upper local bit lines LBL_U.

Each of the lower local bit lines LBL_L may be connected to the lower memory cells MC1 arranged in the vertical direction Z. For example, each of the lower local bit lines LBL_L may be connected to the first lower source/drain regions cSDla of the lower cell transistors cTRa. The lower local bit lines LBL_L may have recessed side surfaces in contact with the lower memory cells MC1.

Each of the upper local bit lines LBL_U may be connected to the upper memory cells MC2 arranged in the vertical direction Z. For example, each of the upper local bit lines LBL_U may be connected to the first upper source/drain regions cSD1b of the upper cell transistors cTRb. The upper local bit lines LBL_U may have recessed side surfaces in contact with the upper memory cells MC2.

Each of the lower local bit lines LBL_L may include a lower pillar pattern 24b and a lower conductive liner 24a covering a side surface and a lower surface of the lower pillar pattern 24b. Each of the upper local bit lines LBL_U may include an upper pillar pattern 224b and an upper conductive liner 224a covering a side surface and an upper surface of the upper pillar pattern 224b.

Each of the lower and upper conductive liners 24a and 224a may include at least one of doped polysilicon, a metal-semiconductor compound, or a metal nitride. For example, each of the lower and upper conductive liners 24a and 224a may include at least one of doped polysilicon, Al, Cu, Ti, Ta, Ru, W, Mo, Pt, Ni, Co, TiN, TaN, WN, NbN, TiAl, TiAIN, TiSi, TiSIN, TaSi, TaSiN, RuTiN, NiSi, or CoSi, and each of the lower and upper pillar patterns 24b and 224b may include a material different from the material of the lower and upper conductive liners 24a and 224a, and may include at least one of doped polysilicon, Al, Cu, Ti, Ta, Ru, W, Mo, Pt, Ni, Co, TiN, TaN, WN, NbN, TiAl, TiAIN, TiSi, TISIN, TaSi, TaSIN, RuTIN, NiSi, or CoSi.

The lower structure STC1 may further include a lower capping insulating layer 18 disposed on the lower cell transistors cTRa. The second lower electrodes 36 may extend upwardly and may penetrate the lower capping insulating layer 18. The lower local bit lines LBL_L may extend upwardly and may penetrate the lower capping insulating layer 18.

The upper structure STC3 may further include an upper capping insulating layer 224 disposed below the upper cell transistors cTRb. The second upper electrodes 236 may extend downwardly and may penetrate the upper capping insulating layer 218. The upper local bit lines LBL_U may extend downwardly and may penetrate the upper capping insulating layer 218.

The lower global bit lines GBL_L may be disposed on the lower capping insulating layer 18. The upper global bit lines GBL_U may be disposed below the upper capping insulating layer 218.

The lower structure STC1 may further include lower bit line contact plugs 39 disposed between the lower global bit lines GBL_L and the lower local bit lines LBL_L, and connecting the lower global bit lines GBL_L to the lower local bit lines LBL_L. Accordingly, each of the lower global bit lines GBL_L may be electrically connected to an N number of the lower local bit lines LBL_L among the lower local bit lines LBL_L by the lower bit line contact plugs 39.

The upper structure STC3 may further include upper bit line contact plugs 239 disposed between the upper global bit lines GBL_U and the upper local bit lines LBL_U, and connecting the upper global bit lines GBL_U to the upper local bit lines LBL_U. Accordingly, each of the upper global bit lines GBL_U may be electrically connected to the N number of the upper local bit lines LBL_U by the upper bit line contact plugs 239.

The lower structure STC1 may further include a lower insulating structure 51 covering the lower memory cells MC1, the lower local bit lines LBL_L, the lower word lines WL_L, the lower capping insulating layer 18, and the lower global bit lines GBL_L.

The upper structure STC3 may further include an upper insulating structure 251 covering the upper memory cells MC2, the upper local bit lines LBL_U, the upper word lines WL_U, the upper capping insulating layer 218, and the upper global bit lines GBL_U.

The intermediate semiconductor body 103 may include intermediate active regions 106a, which may be defined by device isolation regions 106s.

The intermediate structure STC2 may include intermediate transistors pTRa, which may be included in the first peripheral circuits PC1. Each of the intermediate transistors pTRa may include intermediate peripheral source/drain regions pSDa disposed in a corresponding intermediate active region 106a among the intermediate active regions 106a, an intermediate peripheral channel region pCHa between the intermediate peripheral source/drain regions pSDa, and an intermediate peripheral gate pGa on the intermediate peripheral channel region pCHa. Here, the intermediate peripheral gate pGa may include an intermediate peripheral gate electrode pGEa on the intermediate peripheral channel region pCHa and an intermediate peripheral gate dielectric layer pGOa between the intermediate peripheral gate electrode pGEa and the intermediate peripheral channel region pCHa.

The intermediate structure STC2 may further include an intermediate insulating structure 127 disposed on the intermediate semiconductor body 103 and covering the first peripheral circuits PC1 and a backside insulating layer 112 disposed below the intermediate semiconductor body 103.

The lower structure STC1 may further include a lower bonding layer 54 disposed on the lower insulating structure 51. The intermediate structure STC2 may further include a first intermediate bonding layer 115 disposed below the backside insulating layer 112, and a second intermediate bonding layer 142 disposed on the intermediate insulating structure 127. The upper structure STC3 may further include an upper bonding layer 257 disposed below the upper insulating structure 251.

The lower bonding layer 54 may be bonded to the first intermediate bonding layer 115 by a dielectric-dielectric bonding process. Accordingly, a first bonding region JNC1 may be formed between the lower structure STC1 and the intermediate structure STC2.

The lower bonding layer 54 and the first intermediate bonding layer 115 may be dielectric layers which may be used as bonding layers in a dielectric-dielectric bonding process. Each of the lower bonding layer 54 and the first intermediate bonding layer 115 may include a dielectric material and may not include a bonding metal material. For example, each of the lower bonding layer 54 and the first intermediate bonding layer 115 may include at least one of SiO, SiN, SiCN, SiOC, SiON, or SiOCN.

The second intermediate bonding layer 142 may include intermediate bonding metal patterns 139 and an intermediate bonding dielectric layer 136 which may be used as bonding layers in a hybrid bonding process including metal-metal bonding and dielectric-dielectric bonding. The upper bonding layer 257 may include upper bonding metal patterns 245 and an upper bonding dielectric layer 254 which may be used as bonding layers in a hybrid bonding process.

By the hybrid bonding process, the intermediate bonding metal patterns 139 may be bonded to the upper bonding metal patterns 245, and the intermediate bonding dielectric layer 136 may be bonded to the upper bonding dielectric layer 254. Accordingly, a second bonding region JNC2 may be formed between the upper structure STC3 and the intermediate structure STC2.

Each of the intermediate bonding metal patterns 139 and the upper bonding metal patterns 245 may include a bonding metal, for example, copper (Cu), which may be used for metal-metal bonding in the hybrid bonding process, and the intermediate bonding dielectric layer 136 and the upper bonding dielectric layer 254 may include a bonding dielectric, which may be used for dielectric-dielectric bonding in the hybrid bonding process. The bonding dielectric may include at least one of SiO, SiN, SiCN, SiOC, SiON, or SiOCN.

The lower structure STC1 and the intermediate structure STC2 may include lower routing interconnection structures RI_L_WL and RI_L_BL. The lower routing interconnection structures RI_L_WL and RI_L_BL may include the lower word line routing interconnection structures RI_L_WL and the lower bit line routing interconnection structures RI_L_BL described above.

Each of the lower word line routing interconnection structures RI_L_WL may include a first lower word line routing interconnection structure 48w and a second lower word line routing interconnection structure 124w connected to the first lower word line routing interconnection structure 48w. Each of the lower bit line routing interconnection structures RI_L_BL may include a first lower bit line routing interconnection structure 48b and a second lower bit line routing interconnection structure 124b connected to the first lower bit line routing interconnection structure 48b.

Each of the first lower word line routing interconnection structures 48w may be connected to a corresponding lower word line WL_L among the lower word lines WL_L, and each of the second lower word line routing interconnection structures 124w may be connected to a corresponding first word line select transistor STw1 among the first word line select transistors STw1. For example, among the lower word line routing interconnection structures RI_L_WL, the lower word line routing interconnection structure RI_L_WL electrically connecting the first lower word line WL_L1 to the first word line select transistor STw1 may include the first lower word line routing interconnection structure 48w connected to the first lower word line WL_L1, and the second lower word line routing interconnection structure 124w connected to the first word line select transistor STw1.

Each of the first lower bit line routing interconnection structures 48b may be connected to a corresponding lower global bit line GBL_L among the lower global bit lines GBL_L, and each of the second lower bit line routing interconnection structures 124b may be connected to a corresponding bit line select transistor among the first and second bit line select transistors STb1 and STb2.

The lower structure STC1 may include the first lower word line routing interconnection structures 48w and the first lower bit line routing interconnection structures 48b, and the intermediate structure STC2 may include the second lower word line routing interconnection structures 124w and the second lower bit line routing interconnection structures 124b.

Each of the first lower word line routing interconnection structures 48w may include a lower gate contact plug 42w in contact with a corresponding lower word line WL_L among the lower word lines WL_L, and a first lower interconnection 45w on the lower gate contact plug 42w. Each of the second lower word line routing interconnection structures 124w may include a first intermediate routing interconnection structure 121w connected to the first intermediate through-via 118w and the first intermediate through-via 118w.

Each of the first intermediate through-vias 118w may penetrate the intermediate semiconductor body 103, may extend downwardly, may penetrate the first intermediate bonding layer 115 and the lower bonding layer 54, and may be connected to a corresponding first lower interconnection among the first lower interconnections 45w.

Each of the first intermediate routing interconnection structures 121w may be connected to a corresponding first word line select transistor STw1 among the first word line select transistors STw1. For example, as illustrated in FIG. 5, one first intermediate routing interconnection structures 121w may include a contact plug 119a connected to the first word line select transistor STw1 and an interconnection 120a connecting the contact plug 119a to the first intermediate through-via 118w. In FIG. 5, a portion denoted as STw1_PGa may be a peripheral gate pGa of the first word line select transistor STw1, and a portion denoted as STw2_PGa may be a peripheral gate pGa of the second word line select transistor STw2.

Each of the first lower bit line routing interconnection structures 48b may include a lower bit line contact plug 42b and a second lower interconnection 45b on the lower bit line contact plug 42b, which are in contact with a corresponding lower global bit line GBL_L among the lower global bit lines GBL_L. Each of the second lower bit line routing interconnection structures 124b may include a second intermediate routing interconnection structure 121b connected to the second intermediate through-via 118b and the second intermediate through-via 118b. Each of the second intermediate through-vias 118b may penetrate the intermediate semiconductor body 103, may extend downwardly, may penetrate the first intermediate bonding layer 115 and the lower bonding layer 54 and may be connected to a corresponding second lower interconnection among the second lower interconnections 45b. Each of the second intermediate routing interconnection structures 121b may be connected to a corresponding bit line select transistor among the first and second bit line select transistors STb1 and STb2.

The intermediate structure STC2 and the upper structure STC3 may include upper routing interconnection structures RI_U_WL and RI_U_BL. The upper routing interconnection structures RI-U_WL and RI-U_BL may include the upper word line routing interconnection structures RI-U_WL and the upper bit line routing interconnection structures RI-U_BL described above.

Each of the upper word line routing interconnection structures RI_U_WL may include a first upper word line routing interconnection structure 248w and a second upper word line routing interconnection structure 130w connected to the first upper word line routing interconnection structure 248w. Each of the upper bit line routing interconnection structures RI_U_BL may include a first upper bit line routing interconnection structure 248b and a second upper bit line routing interconnection structure 130b connected to the first upper bit line routing interconnection structure 248b.

Each of the first upper word line routing interconnection structures 248w may be connected to a corresponding upper word line WL_U among the upper word lines WL_U, and each of the second upper word line routing interconnection structures 130w may be connected to a corresponding second word line select transistor STw2 among the second word line select transistors STw2. For example, among the upper word line routing interconnection structures RI_U_WL, the upper word line routing interconnection structure RI_U_WL electrically connecting the first upper word line WL_U1 to the first word line select transistor STw1 may include a first upper word line routing interconnection structure 248w connected to the first upper word line WL_U1, and a second upper word line routing interconnection structure 130w connected to the second word line select transistor STw2.

Each of the first upper bit line routing interconnection structures 248b may be connected to a corresponding upper global bit line GBL-U among the upper global bit lines GBL_U, and each of the second upper bit line routing interconnection structures 130b may be connected to a corresponding bit line select transistor among the third and fourth bit line select transistors STb3 and STb4.

The upper structure STC3 may include the first upper word line routing interconnection structures 248w and the first upper bit line routing interconnection structures 248b, and the intermediate structure STC2 may include the second upper word line routing interconnection structures 130w and the second upper bit line routing interconnection structures 130b.

Each of the first upper word line routing interconnection structures 248w may include a 1-1 upper word line interconnection structure 242w and a first upper bonding metal pattern 245w below the 1-1 upper word line interconnection structure 242w connected to a corresponding upper word line WL_U among the upper word lines WL_U.

Each of the 1-1 upper word line interconnection structures 242w may include an upper gate contact plug 240w in contact with a corresponding upper word line WL_U among the upper word lines WL_U and a first connection structure 241w electrically connecting the upper gate contact plug 240w to the first upper bonding metal pattern 245w.

The upper gate contact plugs 240w may vertically overlap the lower gate contact plugs 42w.

Each of the second upper word line routing interconnection structures 130w may include a first intermediate bonding metal pattern 139w bonded to a corresponding first upper bonding metal pattern 245w among the first upper bonding metal patterns 245w and a second connection structure 133w electrically connecting the first intermediate bonding metal pattern 139w to the second word line select transistor STw2. For example, as illustrated in FIG. 5, one second connection structure 133w may include a first contact plug 119b connected to the second word line select transistor STw2, a first interconnection 121b (also referred to as “second intermediate routing interconnection structure”) on the first contact plug 119b, a second contact plug 132a on the first interconnection 121b, and a second interconnection 132b connecting the first intermediate bonding metal pattern 139w to the second contact plug 132a.

In example embodiments, to increase integration density, the first intermediate through-via 118w and the first intermediate bonding metal pattern 139w may vertically overlap one another. Each of the first upper bit line routing interconnection structures 248b may include a 1-1 upper bit line interconnection structure 242b connected to a corresponding upper global bit line GBL_U among the upper global bit lines GBL_U, and a second upper bonding metal pattern 245b below the 1-1 upper bit line interconnection structure 242b.

Each of the second upper bit line routing interconnection structures 130b may include a second intermediate bonding metal pattern 139b bonded to a corresponding second upper bonding metal pattern 245b among the second upper bonding metal patterns 245b, and a third connection structure 133b electrically connecting the second intermediate bonding metal pattern 139b to a corresponding bit line select transistor among the third and fourth bit line select transistors STb3 and STb4.

The upper semiconductor body 203 may include upper active regions 206a, which may be defined by device isolation regions 206s.

The upper structure STC3 may include upper transistors pTRb, which may be included in the second peripheral circuits PC2. Each of the upper transistors pTRb may include an upper peripheral source/drain region pSDb disposed in a corresponding upper active region 206a among the upper active regions 206a, an upper peripheral channel region pCHb between the upper peripheral source/drain regions pSDb, and an upper peripheral gate pGb on the upper peripheral channel region pCHb. Here, the upper peripheral gate pGb may include an upper peripheral gate electrode pGEb on the upper peripheral channel region pCHb and an upper peripheral gate dielectric layer pGOb between the upper peripheral gate electrode pGEb and the upper peripheral channel region pCHb.

The upper structure STC3 may further include an upper insulating structure 285 disposed on the upper semiconductor body 203 and covering the second peripheral circuits PC2, a routing interconnection structure 275 embedded in the upper insulating structure 285 and upper interconnections 280 on the routing interconnection structure 275.

The intermediate structure STC2 and the upper structure STC3 may further include a connection routing structure RI_U_c for electrically connecting the first peripheral circuits PC1 to the second peripheral circuits PC2. The connection routing structure RI_U_c may include a first connection routing structure RI_U_Ca disposed at the same level as the upper word line routing interconnection structures RI_U_WL, and a second connection routing structure RI_U_Cb connected to the first connection routing structure RI_U_Ca, extending upwardly, passing through the upper semiconductor body 203, and configured to be electrically connected to the second peripheral circuit PC2 on the upper semiconductor body 203.

The upper structure STC3 may further include pad patterns 290 for input/output.

At least one of the pad patterns 290 may be connected to at least one of the upper interconnections 280.

The pad patterns 290 may have a shape protruding from the upper insulating structure 285, but example embodiments thereof are not limited thereto. For example, the pad patterns 290 may not be provided, and regions of the upper interconnections 280 exposed by openings 285a of the upper insulating structure 285 may be defined as pad regions 280P for input/output.

In example embodiments, the intermediate transistors pTRa of the first peripheral circuits PC1 may be formed as planar transistors, but example embodiments thereof are not limited thereto. For example, the intermediate transistors pTRa of the first peripheral circuits PC1 may be formed as a fin field-effect transistor (FinFET) or a gate-all-around transistor. The gate-all-around transistor may be a transistor in which a channel may be formed as a nanowire or nanosheet stacked in a vertical direction.

In example embodiments, the upper transistors pTRb of the second peripheral circuits PC2 may be formed as planar transistors, but example embodiments thereof are not limited thereto. For example, the upper transistors pTRb of the second peripheral circuits PC2 may be formed as a fin field-effect transistor (FinFET) or a gate-all-around transistor.

Hereinafter, example embodiments of the semiconductor device 1 will be described. The various example embodiments described below and the example embodiments described above may be combined to form example embodiments. Hereinafter, elements described above may be directly cited without a detailed description, or a description may not be provided. Also, elements described below which may be modified or replaced may be described with reference to the diagrams below, but elements which may be modified, replaced, or added may be combined with one another or with the elements described above to form a semiconductor device according to example embodiments. Also, in the case in which the previously described element includes multiple elements, the example in which the number of elements described above is one will be described.

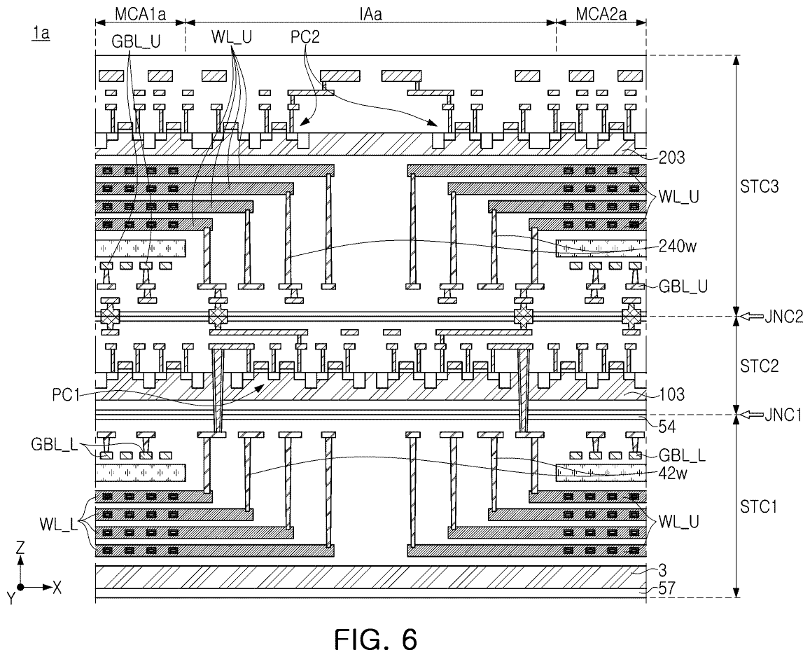

Example embodiments of the semiconductor device described above will be described with reference to FIG. 6. FIG. 6 is a cross-sectional diagram illustrating example embodiments of the semiconductor device described above.

Referring to FIG. 6, a semiconductor device la in the example embodiment may include a first memory cell array region MCA1a, a second memory cell array region MCA2a, and a connection region IAa between the first memory cell array region MCA1a and the second memory cell array region MCA2a. The first memory cell array region MCA1a and the second memory cell array region MCA2a may have a mirror-symmetric structure.

The semiconductor device la may include the lower structure STC1, the intermediate structure STC2, and the upper structure STC3 described above. For example, each of the first and second memory cell array regions MCA1a and MCA2a may include substantially the same elements as the memory cell array region (MCA in FIG. 4A) described above. In the connection region IAa, the region adjacent to the first memory cell array region MCA1a may include substantially the same elements as the connection region (IA in FIG. 4A) described above, and the region adjacent to the second memory cell array region MCA2a may include substantially the same elements as the connection region (IA in FIG. 4A) described above.

The lower word lines WL_L disposed in the first memory cell array region MCA1a and extending into the connection region IAa may be spaced apart from the lower word lines WL_L disposed in the second memory cell array region MCA2a and extending into the connection region IAa. The upper word lines WL_U disposed in the first memory cell array region MCA1a and extending into the connection region IAa may be spaced apart from the upper word lines WL_U disposed in the second memory cell array region MCA2a and extending into the connection region IAa.

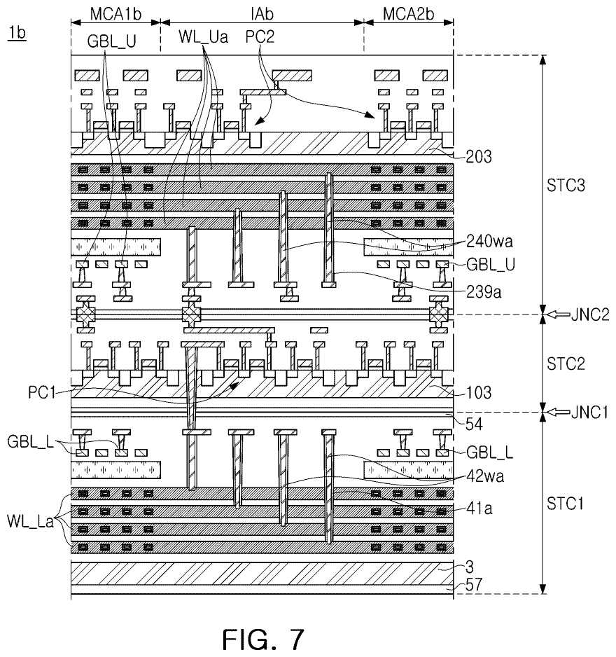

The lower word lines WL_L in the first memory cell array region MCA1a and the lower word lines WL_L in the second memory cell array region MCA2a may be spaced apart from one another in the first direction, and the upper word lines WL_U in the first memory cell array region MCA1a and the upper word lines WL_U in the second memory cell array region MCA2a may be spaced apart from one another in the first direction, but example embodiments thereof are not limited thereto. For example, the lower word lines WL_L in the first memory cell array region MCA1a and the lower word lines WL_L in the second memory cell array region MCA2a may be modified to be connected to one another in the connection region IAa, and the upper word lines WL_U in the first memory cell array region MCA1a and the upper word lines WL_U in the second memory cell array region MCA2a may be modified to be connected to one another in the connection region IAa. Example embodiments of the lower word lines WL_L and the upper word lines WL_U which may be modified as above will be described with reference to FIGS. 7, 8A, 8B, 9, 10, and 11.

First, example embodiments of the semiconductor device described above will be described with reference to FIG. 7. FIG. 7 is a cross-sectional diagram illustrating example embodiments of the semiconductor device described above.

Referring to FIG. 7, a semiconductor device 1b in the example embodiment may include a first memory cell array region MCA1b, a second memory cell array region MCA2b, and a connection region IAb between the first memory cell array region MCA1b and the second memory cell array region MCA2b. The first memory cell array region MCA1b and the second memory cell array region MCA2b may have a mirror symmetric structure.

The semiconductor device 1b may include the lower structure STC1, the intermediate structure STC2 and the upper structure STC3 described above. For example, each of the first and second memory cell array regions MCA1b and MCA2b may include substantially the same elements as the memory cell array region (MCA in FIG. 4A) described above.

The lower word lines WL_L described above with reference to FIG. 6 may be replaced by lower word lines WL_La disposed in the first memory cell array region MCA1b, the connection region IAb and the second memory cell array region MCA2b. Each of the lower word lines WL_La may cross the first memory cell array region MCA1b, the connection region IAb and the second memory cell array region MCA2b.

The upper word lines WL_U described above with reference to FIG. 6 may be replaced by upper word lines WL_Ua disposed in the first memory cell array region MCA1b, the connection region IAb and the second memory cell array region MCA2b. Each of the upper word lines WL_Lb may cross the first memory cell array region MCA1b, the connection region IAb and the second memory cell array region MCA2b.

The lower gate contact plugs (42w in FIG. 4D) described above may be replaced with lower gate contact plugs 42wa connected to the lower word lines WL_La, respectively, in the connection region IAb. The upper gate contact plugs (240w in FIG. 4D) described above may be replaced with upper gate contact plugs 240wa connected to the upper word lines WL_Ua, respectively, in the connection region IAb.

The lower structure STC1 may further include lower insulating spacers 41a disposed on side surfaces of the lower gate contact plugs 42wa. The upper structure STC3 may further include upper insulating spacers 239a disposed on side surfaces of the upper gate contact plugs 240a.

Among the lower gate contact plugs 42wa, contact plug 42wa connected to the lowermost word line among the lower word lines WL_La may penetrate the other lower word lines, and the lower insulating spacer 41a may electrically insulate the contact plug 42wa from the other lower word lines. Among the upper gate contact plugs 240wa, contact plug 240wa connected to the uppermost word line among the upper word lines WL_Ua may penetrate the other upper word lines, and the upper insulating spacer 239a may electrically insulate the contact plug 240wa from the other upper word lines.

A structure including the lower word lines WL_La and the lower gate contact plugs 42wa and a structure including the upper word lines WL_Ua and the upper gate contact plugs 240wa may be a mirror symmetric structure. The lower word lines WL_La may vertically overlap the upper word lines WL_Ua, and the lower gate contact plugs 42wa may vertically overlap the upper gate contact plugs 240wa.

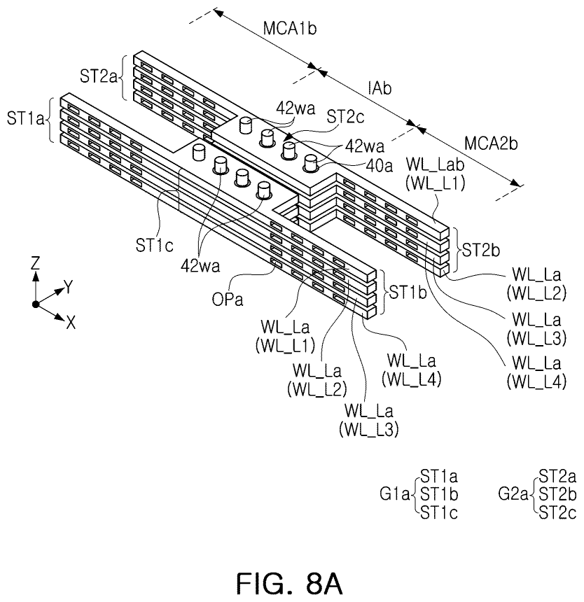

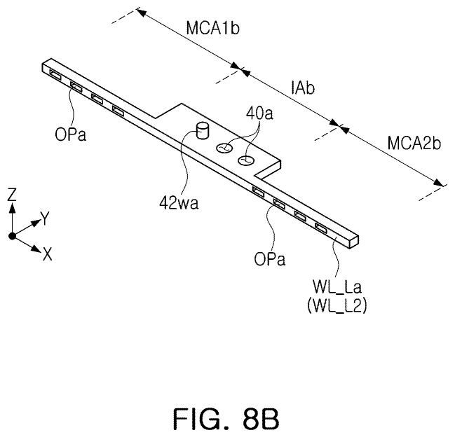

Example embodiments of the gate contact plugs 42wa and 240wa and the word lines WL_La and WL_Ua described with reference to FIG. 7 will be described with reference to FIGS. 8A and 8B. FIG. 8A is a perspective diagram illustrating example embodiments of the lower word lines WL_La and the gate contact plugs 42wa described with reference to FIG. 7, and FIG. 8B is a perspective diagram illustrating one lower word line among the lower word lines and one gate contact plug among the gate contact plugs.

Referring to FIGS. 8A and 8B together with FIG. 7, stack groups Gla and G2a including a first stack group Gla and a second stack group G2a spaced apart from one another in the second direction Y may be disposed. Each of the stack groups Gla and G2a may include the lower word lines WL_La stacked in the vertical direction.

In each of the stack groups Gla and G2a, the lower word lines WL_La may include the first lower word line WL_L1, the second lower word line WL_L2 below the first lower word line WL_L1, the third lower word line WL_L3 below the second lower word line WL_L2, and the fourth lower word line WL_L4 below the third lower word line WL_L2.

The first stack group Gla may include a first stack region STla positioned in the first memory cell array region MCA1b, a second stack region ST1b positioned in the second memory cell array region MCA2b, and a third stack region ST1c positioned in the connection region IAb.

The second stack group G2a may include a fourth stack region ST2a positioned in the first memory cell array region MCA1b, a fifth stack region ST2b positioned in the second memory cell array region MCA2b, and a sixth stack region ST2c positioned in the connection region IAb.

Each of the lower word lines WL_La may have a first width in the first and second memory cell array regions MCA1b and MCA2b in the second direction Y, and a second width greater than the first width in the connection region IAb in the second direction Y.

In the first and second memory cell array regions MCA1b and MCA2b, each of the lower word lines WL_La may have horizontal through-holes OPa as in FIG. 4D. The horizontal through-holes OPa may penetrate the lower word lines WL_La in the second direction Y.

Among the lower word lines WL_La, each of the word lines disposed at a level higher than a level of the lowermost word line WL_L4 among the lower word lines WL_La may have at least one vertical through-hole 40a. For example, the first lower word line WL_L1 may have vertical through-holes 40a penetrated by lower gate contact plugs 42wa connected to the second, third, and fourth lower word lines WL_L2, WL_L3, and WL_L4, and the second lower word line WL_L2 may have vertical through-holes 40a penetrated by lower gate contact plugs 42wa connected to the third and fourth lower word lines WL_L3 and WL_L4. Among the lower gate contact plugs 42wa, the lower gate contact plug passing through the vertical through-hole 40a may be electrically insulated from the lower word line WL_L having the vertical through-hole 40a by the lower gate insulating spacer (41a in FIG. 7).

A plurality of the lower gate contact plugs 42wa may be arranged in the first direction X.

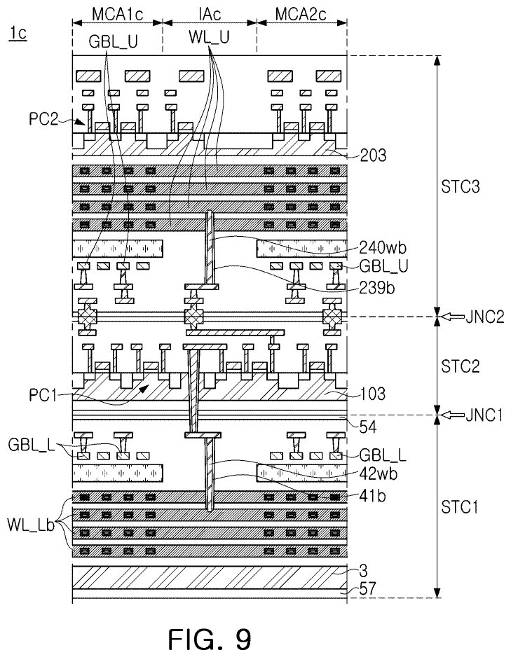

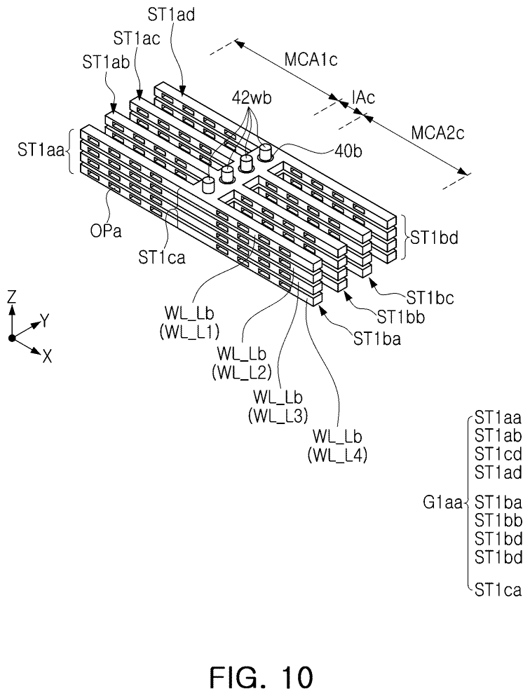

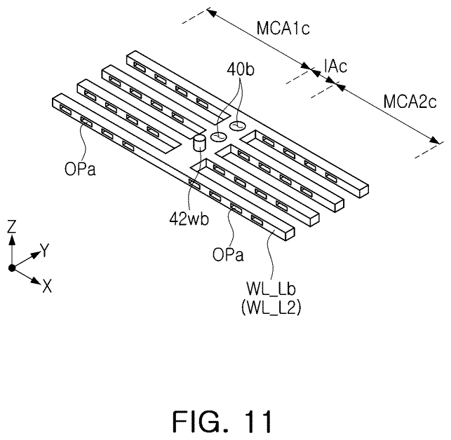

Example embodiments of the semiconductor device described above will be described with reference to FIGS. 9, 10, and 11. FIG. 9 is a cross-sectional diagram illustrating example embodiments of the semiconductor device described above, FIG. 10 is a perspective diagram illustrating example embodiments of the lower word lines WL_Lb and the lower gate contact plugs 42wb in FIG. 9, and FIG. 11 is a perspective diagram illustrating one lower word line among the lower word lines and one gate contact plug among the lower gate contact plugs.

Referring to FIGS. 9, 10, and 11, the semiconductor device 1c in the example embodiment may include a first memory cell array region MCA1c, a second memory cell array region MCA2c, and a connection region IAc between the first memory cell array region MCA1c and the second memory cell array region MCA2c. The first memory cell array region MCA1c and the second memory cell array region MCA2c may have mirror-symmetric structures. The semiconductor device 1c may include the lower structure STC1, the intermediate structure STC2 and the upper structure STC3 described above. For example, each of the first and second memory cell array regions MCA1c and MCA2c may include substantially the same elements as the memory cell array region (MCA in FIG. 4A) described above.

The lower word lines WL_La described with reference to FIGS. 7, 8A, and 8B above may be replaced with lower word lines WL_Lb disposed in the first memory cell array region MCA1c, the connection region IAc and the second memory cell array region MCA2c. Each of the lower word lines WL_Lb may cross the first memory cell array region MCA1c, the connection region IAc and the second memory cell array region MCA2c, and may include first portions ST1aa, ST1ab, ST1ac, and ST1ad spaced apart from one another in the second direction Y in the first memory cell array region MCA1b, and may include second portions ST1b a, ST1b b, ST1b c, and ST1bd spaced apart from one another in the second direction Y in the second memory cell array region MCA2b, and may include a connection portion ST1ca connecting the first portions ST1aa, ST1ab, ST1a c , and ST1ad to the second portions ST1ba, ST1bb, ST1bc, and ST1bd in the connection region IAc.

The upper word lines WL_U described in the above FIG. 6 may be replaced by upper word lines WL_Ub having a mirror-symmetric structure with the lower word lines WL_Lb.

The lower gate contact plugs (42w in FIG. 4D) described above may be replaced with lower gate contact plugs 42wb connected to the lower word lines WL_Lb, respectively, in the connection region IAc. The upper gate contact plugs (240w in FIG. 4D) described above may be replaced with upper gate contact plugs 240wb connected to the upper word lines WL_Ub, respectively, in the connection region IAc.

The lower structure STC1 may further include lower insulating spacers 41b disposed on side surfaces of the lower gate contact plugs 42wb. The upper structure STC3 may further include upper insulating spacers 239b disposed on side surfaces of the upper gate contact plugs 240b.

Among the lower gate contact plugs 42wb, the contact plug 42wb connected to the lowermost word line among the lower word lines WL_Lb may penetrate the other lower word lines, and the lower insulating spacer 41b may electrically insulate the contact plug 42wb from the other lower word lines. Among the upper gate contact plugs 240wb, the contact plug 240wb connected to the uppermost word line among the upper word lines WL_Ub may penetrate the other upper word lines, and the upper insulating spacer 239b may electrically insulate the contact plug 240wb from the other upper word lines.

A structure including the lower word lines WL_Lb and the lower gate contact plugs 42wb and a structure including the upper word lines WL_Ub and the upper gate contact plugs 240wb may be a mirror-symmetric structure. The lower word lines WL_Lb may vertically overlap the upper word lines WL_Ub, and the lower gate contact plugs 42wb may vertically overlap the upper gate contact plugs 240wb.

The lower word lines WL_Lb may include a first lower word line WL_L1, a second lower word line WL_L2 below the first lower word line WL_L1, a third lower word line WL_L3 below the second lower word line WL_L2, and a fourth lower word line WL_L4 below the third lower word line WL_L2.

In the first and second memory cell array regions MCA1b and MCA2b, each of the lower word lines WL_Lb may have horizontal through-holes OPa as in FIG. 4D. The horizontal through-holes OPa may penetrate the lower word lines WL_Lb in the second direction Y.

Among the lower word lines WL_Lb, each of the word lines disposed at a level higher than a level of the lowermost word line WL_L4 among the lower word lines WL_Lb may have at least one vertical through-hole 40b. For example, the first lower word line WL_L1 may have vertical through-holes 40b penetrated by lower gate contact plugs 42wb connected to the second, third, and fourth lower word lines WL_L2, WL_L3, and WL_L4, and the second lower word line WL_L2 may have vertical through-holes 40b penetrated by lower gate contact plugs 42wb connected to the third and fourth lower word lines WL_L3 and WL_L4. Among the lower gate contact plugs 42wb, the lower gate contact plug passing through the vertical through-hole 40b may be electrically insulated from the lower word line WL_L having the vertical through-hole 40b by the lower gate insulating spacer (41b in FIG. 9).

A plurality of lower gate contact plugs 42wb among the lower gate contact plugs 42wb may be arranged in the second direction Y.

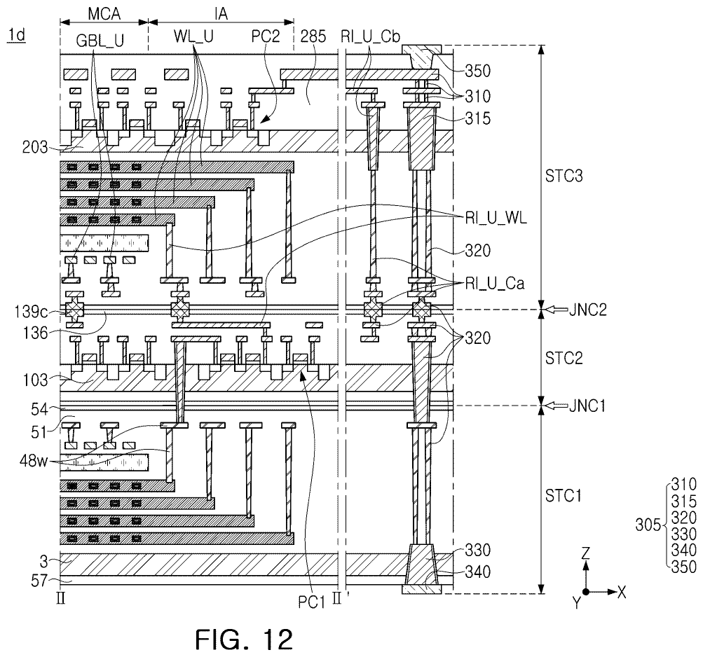

Referring to FIG. 12, example embodiments of the semiconductor device described above will be described. FIG. 12 is a cross-sectional diagram illustrating example embodiments of the semiconductor device described above.

Referring to FIG. 12, a semiconductor device 1d in the example embodiment may further include an input/output routing structure 305. The input/output routing structure 305 may have a shape of penetrating the first, second, and third structures STC1, STC2, and STC3. For example, the input/output routing structure 305 may include a first input/output pad pattern 350, an upper through-electrode 315 passing through the upper semiconductor body 203, an upper connection portion 310 between the first input/output pad pattern 350 and the upper through-electrode 315, a lower connection portion 320 disposed below the upper through-electrode 315 and disposed at the same level as the upper word line routing interconnection structures RI_U_WL and the first lower word line routing interconnection structure 48w, a lower through-electrode 330 disposed below the lower connection portion 320 and passing through the lower base 3, and a second input/output pad pattern 340 below the lower through-electrode 330.

The first input/output pad pattern 350 and the second input/output pad pattern 340 may vertically overlap one another.

The input/output routing structure 305 may be electrically connected to the circuit for input/output of data or commands, or input of power/ground among the second peripheral circuits PC2.

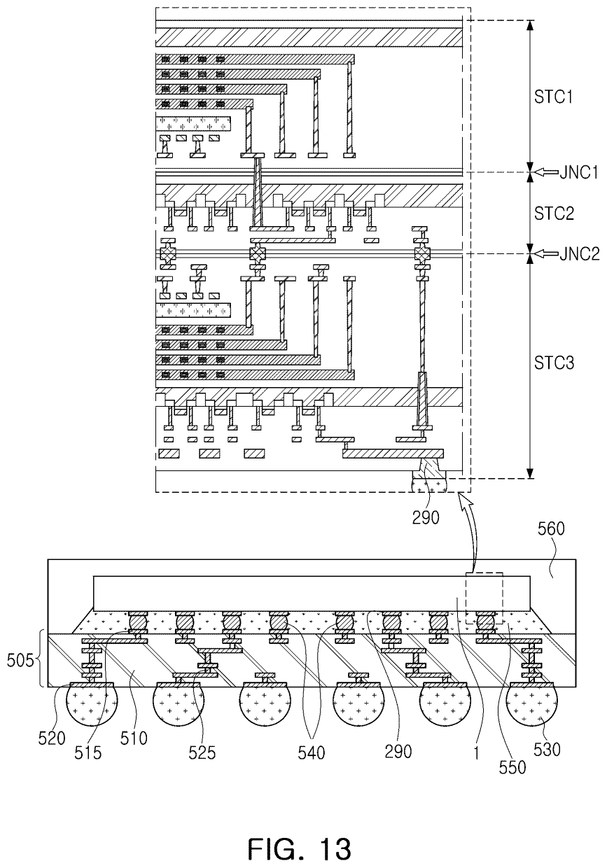

In the description below, example embodiments of the semiconductor device described above will be described with reference to FIG. 13. FIG. 13 is a cross-sectional diagram illustrating a semiconductor device according to example embodiments.

Referring to FIG. 13, a semiconductor device according to example embodiments may include a package substrate 505 and a semiconductor chip 1 on the package substrate 505.

In example embodiments, the semiconductor chip 1 may be one of the semiconductor chips in the example embodiments described above. For example, the semiconductor device according to the example embodiment described above with reference to FIGS. 1 to 12 may be mounted on the package substrate 505. For example, the semiconductor device 1 including the first, second, and third structures STC1 and STC2, and STC3 described with reference to FIGS. 4A to 4E may be mounted on the package substrate 505 in the form of a semiconductor chip.

The package substrate 505 may be implemented as a printed circuit board or a redistribution substrate. The package substrate 505 may include first pads 515 disposed on an upper surface of the package substrate 505, second pads 520 disposed on a lower surface of the package substrate 505, and internal interconnections 525 electrically connecting the first and second pads 515 and 520 to one another.

Conductive bumps 85 connecting the pad patterns 290 of the third structures STC3 of the semiconductor chip 1 to the first pads 515 of the package substrate 505 may be disposed. An underfill material 550 filling a space between the semiconductor chip 1 and the package substrate 505 and a mold layer 560 covering the semiconductor chip 1 on the package substrate 505 may be disposed.

Accordingly, the semiconductor chip 1 may be mounted on the package substrate 505 in a flip chip structure.

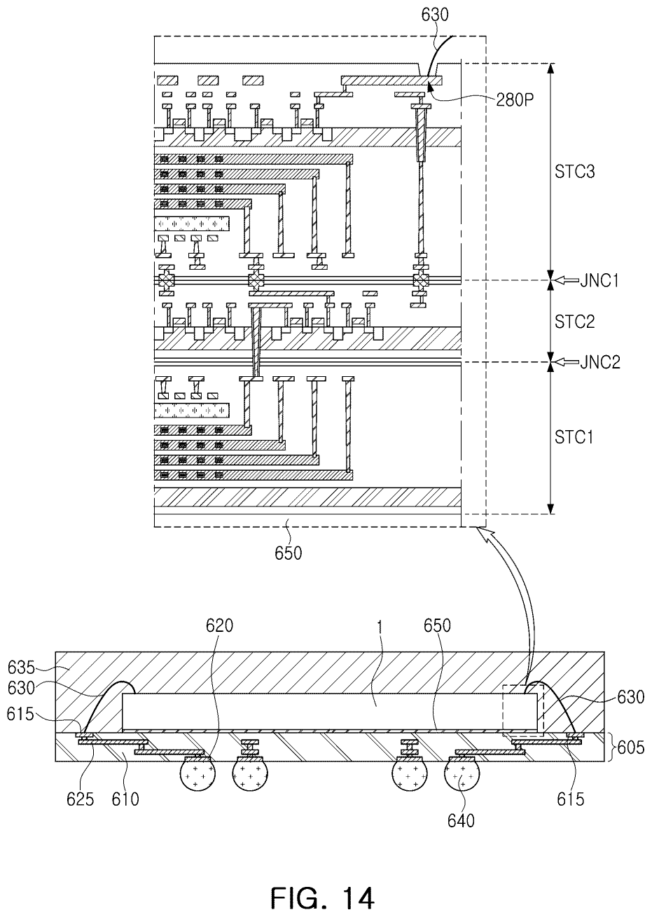

In the description below, example embodiments of the semiconductor device described above will be described with reference to FIG. 14. FIG. 14 is a cross-sectional diagram illustrating a semiconductor device according to example embodiments.

Referring to FIG. 14, a semiconductor device according to example embodiments may include a package substrate 605 and a semiconductor chip 1 on the package substrate 605.

In example embodiments, the semiconductor chip 1 may be one of the semiconductor chips in the example embodiments described above. For example, a semiconductor device according to one of the example embodiments described above with reference to FIGS. 1 to 12 may be mounted on the package substrate 605. For example, the semiconductor device 1 including the first, second, and third structures STC1 and STC2, and STC3 described with reference to FIGS. 4A to 4E may be mounted on the package substrate 605 in the form of a semiconductor chip.

The package substrate 605 may include first pads 615 disposed on a surface facing the semiconductor chip 1, second pads 620 disposed on a lower surface of the package substrate 605, and internal interconnections 625 electrically connecting the first pads 615 to the second pads 620. An adhesive layer 126 may be disposed between the semiconductor chip 1 and the package substrate 605.

The semiconductor chip 1 may include pad regions 280P for input/output as described above. Wires 630 electrically connecting the pad regions 280P of the semiconductor chip 1 to the first pads 615 of the package substrate 605 may be disposed. A mold layer 635 covering the semiconductor chip 1 and the wires 630 may be disposed on the package substrate 605. The semiconductor chip 1 may be mounted on the package substrate 605 by wire bonding.

In example embodiments, one semiconductor chip 1 may be mounted on the package substrate 605, but example embodiments thereof are not limited thereto. For example, a plurality of the semiconductor chip 1 may be mounted on the package substrate 605.

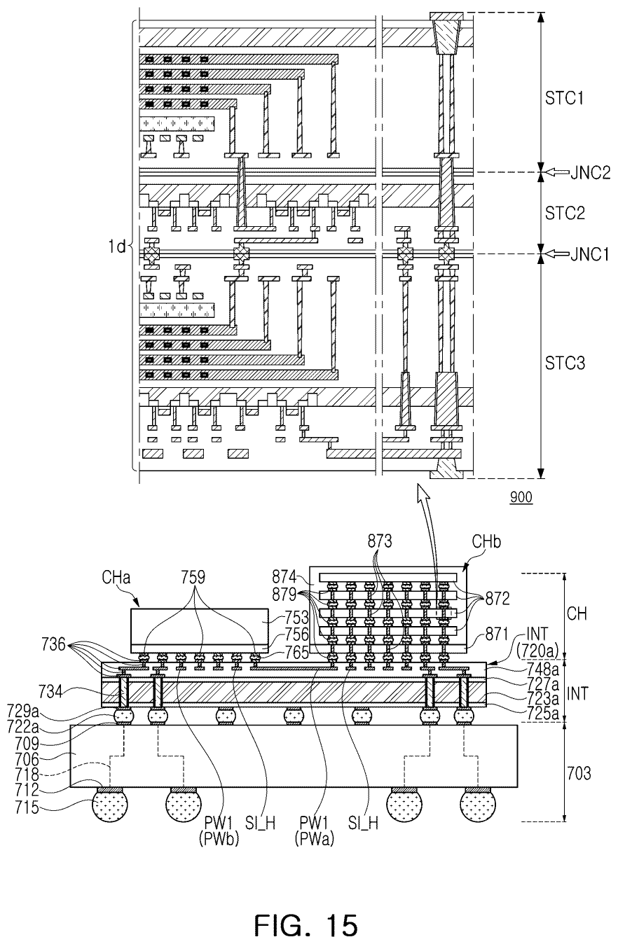

In the description below, example embodiments of the semiconductor device described above will be described with reference to FIG. 15. FIG. 15 is a cross-sectional diagram illustrating a semiconductor device according to example embodiments.

Referring to FIG. 15, the semiconductor device 900 in the example embodiment may include a package substrate 703, an interposer INT on the package substrate 703, and a first chip structure CHa and a second chip structure CHb mounted on the interposer INT.

In an example, the package substrate 703 may include a substrate body 706, lower pads 712 in a lower portion of the substrate body 706, connection patterns 715 disposed below the lower pads 712 and electrically connected to the lower pads 712, upper pads 709 disposed on the substrate body 706, and internal interconnections 718 electrically connecting the lower pads 712 to the upper pads 709 in the substrate body 706. The connection patterns 715 may be solder balls including a solder material such as SnAg or SnAgCu. The package substrate 703 may be implemented as a printed circuit board.

The interposer INT may include an interposer substrate 723a, a first lower insulating layer 725a below the interposer substrate 723a, a first upper insulating layer 727a on the interposer substrate 723a, a first insulating structure 748a on the first upper insulating layer 727a, and interconnection structures 736 in the first insulating structure 748a. The interconnection structures 736 may include a power/ground path and a signal path.

The second chip structure CHb may include a lower chip 871, and a plurality of semiconductor chips 872 stacked and spaced apart from one another in a vertical direction on the lower chip 871.

Each of the plurality of semiconductor chips 872 may include the semiconductor device 1d described with reference to FIG. 12. Accordingly, each of the plurality of semiconductor chips 872 may include the first, second, and third structures STC1 and STC2, and STC3 of the semiconductor device 1d described with reference to FIG. 12. In each of the plurality of semiconductor chips 872, the third structure STC3 may be disposed below the first structure STC1.

The second chip structure CHb may further include bump structures 879 for interconnecting the lower chip 871 to the plurality of semiconductor chips 872. The lower chip 871 may further include through-electrodes 873 for electrically connecting the plurality of semiconductor chips 872 to the plurality of interposer INT.

The plurality of semiconductor chips 872 may include through-electrodes 873 for interconnecting the plurality of semiconductor chips 872.

In example embodiments, the through-electrodes 773 of the plurality of semiconductor chips 872 may be the input/output routing structure 305 described with reference to FIG. 12.

The second chip structure CHb may further include a mold layer 874 covering a lower portion of each of the plurality of semiconductor chips 872 on the lower chip 871 and covering the plurality of semiconductor chips 872. The second chip structure CHb may be mounted on the interposer INT in a flip chip manner. The lower chip 871 may be configured as a buffer chip or a logic chip.

The conductive bumps 65 connecting the interposer INT to pads 759 of the first chip structure CHa may be disposed. The first chip structure CHa may be configured as a processor unit. For example, the first chip structure CHa may include a central processing unit (CPU), a graphics processing unit (GPU), and a digital signal processor (DSP). The first chip structure CHa may include an application processor (AP). The application processor (AP) may be configured as a wireless communication application or an application specific IC (ASIC).

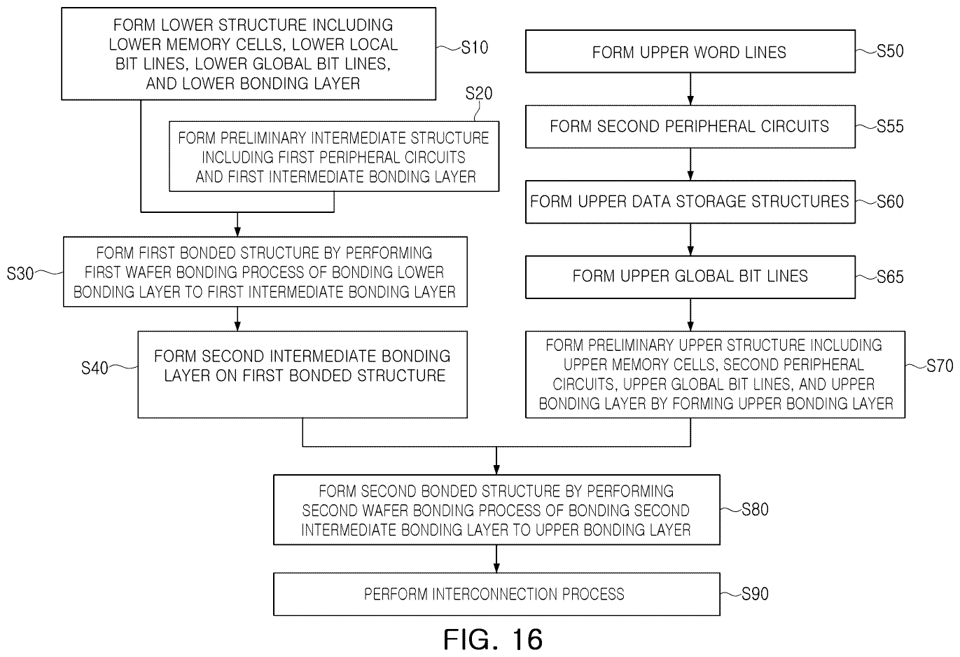

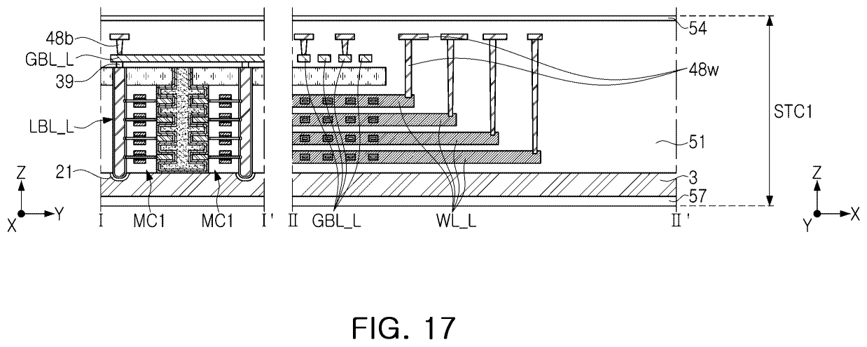

In the description below, a method of manufacturing a semiconductor device according to example embodiments will be described with reference to FIGS. 16, 17, 18, 19A, 19B, 20A, 20B, 20C, and 21. As for FIGS. 16, 17, 18, 19A, 19B, 20A, 20B, 20C, and 21, FIG. 16 is a process flowchart illustrating a method of manufacturing a semiconductor device according to example embodiments, and FIGS. 17, 18, 19A, 19B, 20A, 20B, 20C, and 21 are cross-sectional diagrams illustrating a method of manufacturing a semiconductor device according to example embodiments. In the description below, descriptions of elements which may be understood from the example embodiments of the semiconductor device described above may not be provided.

Referring to FIGS. 16 and 17, a lower structure STC1 may be formed. For example, the lower structure STC1 including lower memory cells MC1, lower local bit lines LBL_L, lower global bit lines GBL_L, and lower bonding layer 54 may be formed (S10). As described above, each of the lower memory cells MC1 may include a lower cell transistor (cTRa in FIG. 4B) and a lower data storage structure (DSa in FIG. 4B). As described above, the lower structure STC1 may include lower word lines WL_L connected to the lower memory cells MC1. The lower bonding layer 54 may include at least one of SiO, SiN, SiCN, SiOC, SiON, or SiOCN.

Forming the lower structure STC1 may include forming the lower memory cells MC1, the lower word lines WL_L, and the lower local bit lines LBL_L on the lower base 3, forming lower global bit lines GBL_L connected to the lower local bit lines LBL_L, forming first lower word line routing interconnection structures 48w connected to the lower word lines WL_L and first lower bit line routing interconnection structures 48b connected to the lower global bit lines GBL_L, forming a lower insulating structure 51 covering the first lower word line routing interconnection structures 48w and the first lower bit line routing interconnection structures 48b, forming the lower bonding layer 54 on the lower insulating structure 51, and forming a protective insulating layer 57 below the lower base 3.

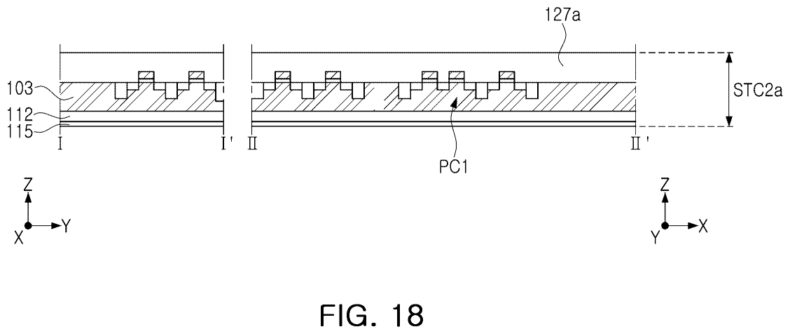

Referring to FIGS. 16 and 18, a preliminary intermediate structure STC2a including first peripheral circuits PC1 and a first intermediate bonding layer 115 may be formed (S20). The first intermediate bonding layer 115 may include at least one of SiO, SiN, SiCN, SiOC, SiON, or SiOCN.

Forming the preliminary intermediate structure STC2a may include forming the first peripheral circuits PC1 on the intermediate semiconductor body 103, forming an insulating structure 127a covering the first peripheral circuits PC1 on the intermediate semiconductor body 103, forming a backside insulating layer 112 covering a lower surface of the intermediate semiconductor body 103, and forming the first intermediate bonding layer 115 covering the backside insulating layer 112.

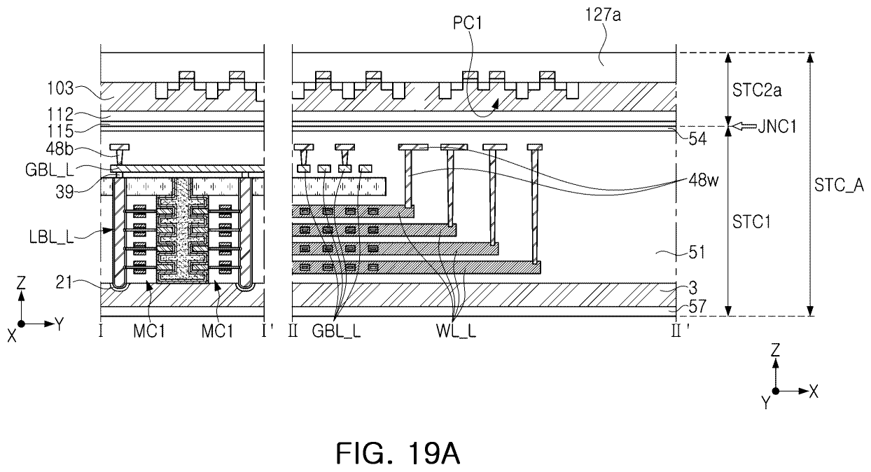

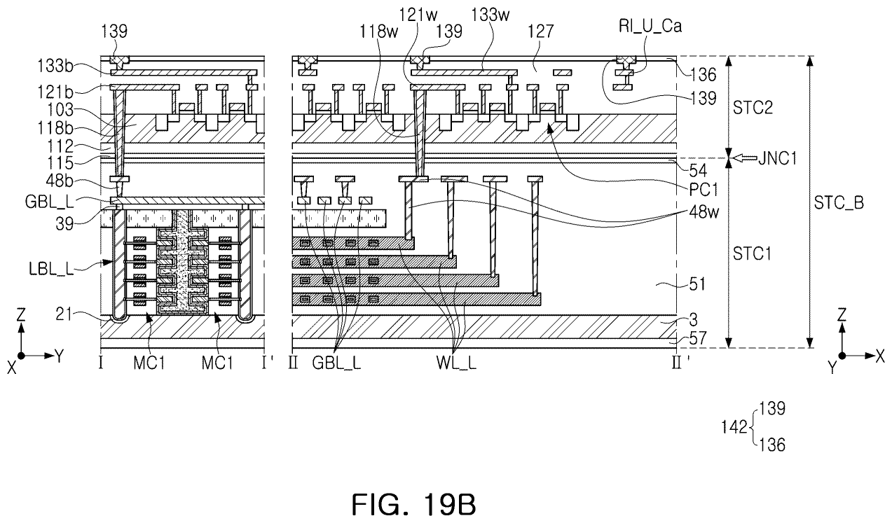

Referring to FIGS. 16 and 19A, a first wafer bonding process of bonding the lower bonding layer 54 to the first intermediate bonding layer 115 may be performed to form a first bonded structure STC_a (S30). The first wafer bonding process may be a dielectric-dielectric bonding process.

Referring to FIGS. 16 and 19B, a second intermediate bonding layer 142 may be formed on the first bonded structure STC_a (S40).

The second intermediate bonding layer 142 may include an intermediate bonding dielectric layer 136 and intermediate bonding metal patterns 139. The intermediate bonding dielectric layer 136 may include at least one of SiO, SiN, SiCN, SiOC, SiON, or SiOCN. The intermediate bonding metal patterns 139 may include copper.

Forming the intermediate bonding dielectric layer 136 may include forming a second lower word line routing interconnection structure 124w, a second lower bit line routing interconnection structure 124b, a second connection structure 133w, and a third connection structure 133b, forming an intermediate bonding dielectric layer 136 on the intermediate insulating structure 127, and forming intermediate bonding metal patterns 139 having upper surfaces coplanar with an upper surface of the intermediate bonding dielectric layer 136. Accordingly, a bonding structure STC_b including the first and second structures STC1 and STC2 bonded to one another may be formed.

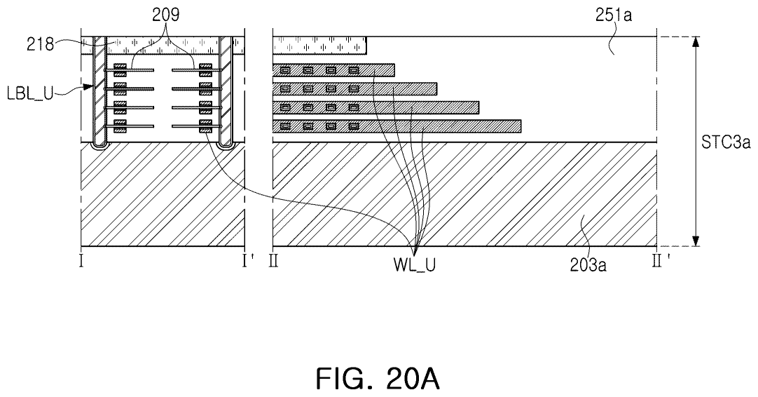

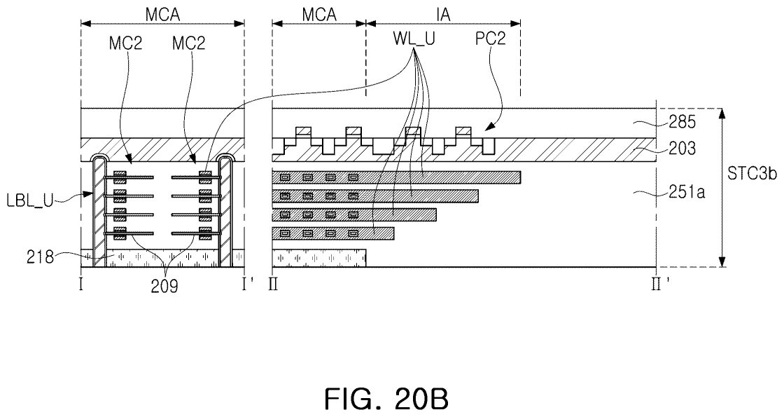

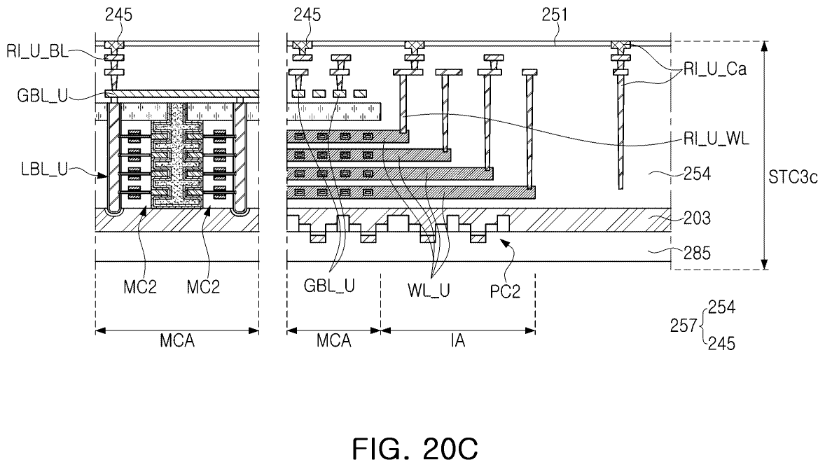

Referring to FIGS. 16 and 20A, upper word lines WL_U may be formed (S50). For example, upper cell active patterns 209 may be formed on preliminary upper semiconductor body 203a, and upper word lines WL_U surrounding the cell active patterns 209 and extending in the second direction may be formed.

In example embodiments, upper local bit lines LBL_U may be formed. For example, upper capping insulating layer 218 disposed at a level higher than a level of the cell active patterns 209 may be formed, and upper local bit lines LBL_U penetrating the upper capping insulating layer 218 and connected to the cell active patterns 209 may be formed.

An insulating structure 251a covering the upper word lines WL_U and having an upper surface coplanar with the upper surface of the upper capping insulating layer 218 may be formed.

Referring to FIGS. 16 and 20B, by reducing a thickness of the preliminary upper semiconductor body 203a, the upper semiconductor body 203 may be formed. Second peripheral circuits PC2 may be formed (S55). The second peripheral circuits PC2 may be formed on the upper semiconductor body 203. An insulating structure 285 covering the second peripheral circuits PC2 may be formed on the upper semiconductor body 203.

Referring to FIGS. 16 and 20C, upper data storage structures (DSb in FIG. 4C) may be formed (S60). Upper cell transistors (cTRb in FIG. 4C) connected to the upper data storage structures (DSb in FIG. 4C) may be formed. The upper data storage structures (DSb in FIG. 4C) and the upper cell transistors (cTRb in FIG. 4C) may be included in upper memory cells MC2.

The upper global bit lines GBL_U may be formed (S65). The upper global bit lines GBL_U may be electrically connected to the upper local bit lines LBL_U on the upper local bit lines LBL_U.

The preliminary upper structure STC3c may be formed. For example, by forming the upper bonding layer 257, the preliminary upper structure STC3c including the upper memory cells MC2, the second peripheral circuits PC2, the upper global bit lines GBL_U, and the upper bonding layer 257 may be formed (S70).

The upper bonding layer 257 may include upper bonding metal patterns 245 and an upper bonding dielectric layer 254. The upper bonding dielectric layer 254 may be formed on an upper insulating structure 251 covering the upper global bit lines GBL_U. The upper bonding metal patterns 245 may have upper surfaces coplanar with an upper surface of the upper bonding dielectric layer 254. The upper bonding dielectric layer 254 may include at least one of SiO, SiN, SiCN, SiOC, SiON, or SiOCN. The upper bonding metal patterns 245 may include a metal such as copper.

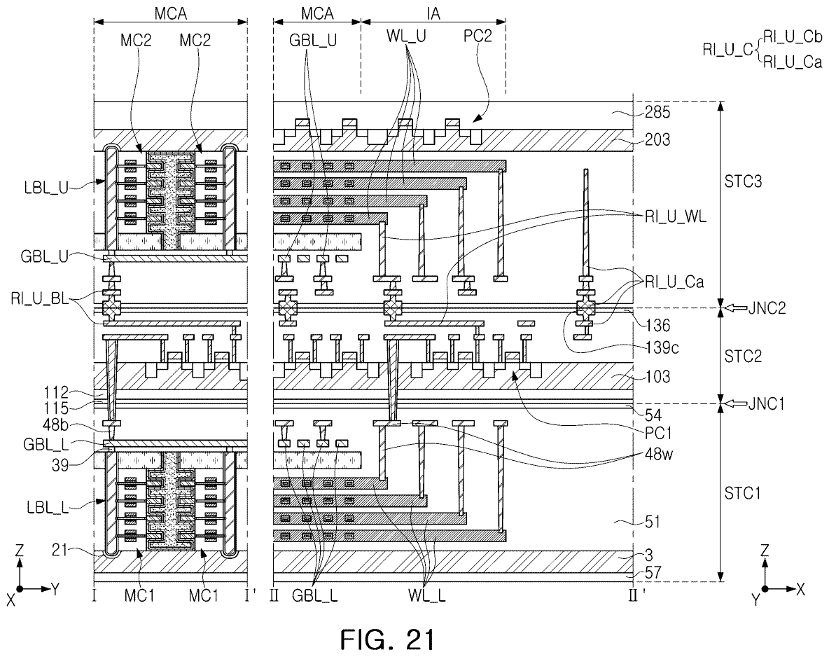

Referring to FIGS. 16 and 21, a second wafer bonding process of bonding the second intermediate bonding layer 142 to the upper bonding layer 257 may be performed to form a second bonded structure (S80). The upper bonding metal patterns 245 and the intermediate bonding metal patterns 139 may be bonded to one another by the second wafer bonding process, and the upper bonding dielectric layer 254 and the intermediate bonding dielectric layer 136 may be bonded to one another by the second wafer bonding process.

Referring to FIGS. 4A to 4E, together with FIG. 16, an interconnection process may be performed (S90). The interconnection process may be a process for forming the routing interconnection structure 275, the upper interconnections 280, the second connection routing structure RI_U_Cb and pad patterns 290 for electrically connecting the second peripheral circuits PC2.

According to example embodiments, a method of manufacturing a semiconductor device includes forming a lower structure including lower memory cells and a lower bonding layer; forming a preliminary intermediate structure including first peripheral circuits and a first intermediate bonding layer; forming a first bonded structure by performing a first wafer bonding process for bonding the lower bonding layer to the first intermediate bonding layer; forming a second intermediate bonding layer on the preliminary intermediate structure of the first bonded structure; forming an upper structure including upper memory cells, second peripheral circuits and an upper bonding layer; and forming a second bonded structure by performing a second wafer bonding process for bonding the second intermediate bonding layer and the upper bonding layer.

Each of the lower bonding layer and the first intermediate bonding layer may include a dielectric material and may not include a bonding metal material.

The second intermediate bonding layer may include a first bonding dielectric layer and first bonding metal patterns. The upper bonding layer may include a second bonding dielectric layer and second bonding metal patterns. The first and second bonding dielectric layers may be bonded to one another by the second wafer bonding process, and the first bonding metal patterns and the second bonding metal patterns may be bonded to one another by the second wafer bonding process.

The lower structure may further include lower word lines connected to the lower memory cells; and lower local bit lines connected to the lower memory cells. The upper structure may further include upper word lines connected to the upper memory cells; and upper local bit lines connected to the upper memory cells.

The first peripheral circuits may include sub-word line select circuits and sub-word line drivers connected to the sub-word line select circuits.

The first peripheral circuits may further include bit line select circuits and bit line sense amplifiers connected to the bit line select circuits.

The preliminary upper structure may further include upper global bit lines connected to the upper local bit lines. The upper global bit lines may be formed after forming the upper memory cells and the second peripheral circuits.

Forming the upper structure may include forming upper memory cells on a preliminary upper semiconductor body; forming an upper semiconductor body by reducing a thickness of the preliminary upper semiconductor body; forming second peripheral circuits on the upper semiconductor body; and forming the upper bonding layer.

The upper semiconductor body may be disposed between the upper memory cells and the second peripheral circuits.

The second intermediate bonding layer may include a first bonding dielectric layer and first bonding metal patterns.

Forming the upper bonding layer may include forming an insulating structure covering the upper memory cells on the upper semiconductor body; forming a second bonding dielectric layer on the insulating structure; and forming second bonding metal patterns coplanar with an upper surface of the second bonding dielectric layer. The first and second bonding dielectric layers may be bonded to one another by the second wafer bonding process, and the first bonding metal patterns and the second bonding metal patterns may be bonded to one another by the second wafer bonding process.

The method may further include forming an upper interconnection. The upper interconnection may be formed on the upper semiconductor body after forming the second bonded structure.

According to the aforementioned example embodiments, a semiconductor device including a lower structure including lower memory cells, an intermediate structure bonded to the lower structure and including first peripheral circuits, and an upper structure bonded to the intermediate structure and including upper memory cells may be provided.

Also, the first peripheral circuits of the intermediate structure may include word line select circuits connected to lower word lines of the lower structure and upper word lines of the upper structure, and sub-word line drivers connected to the word line select circuits.

Also, the second peripheral circuits of the intermediate structure may include bit line select circuits connected to lower bit lines of the lower structure and upper bit lines of the upper structure, and bit line sense amplifiers connected to the bit line select circuits.

Also, the word line select circuits may reduce the total number of the sub-word line drivers, and the bit line select circuits may reduce the total number of the bit line sense amplifiers. Accordingly, even when the numbers of the lower memory cells and the upper memory cells are increased, a space for disposing the sub-word line drivers and the bit line sense amplifiers may be ensured.

Also, the upper memory cells and the lower memory cells opposing one another with the intermediate structure interposed therebetween may be disposed in a symmetrical structure. Accordingly, since the upper memory cells and the lower memory cells may be formed in a symmetrical structure, uniformity of the semiconductor device may be improved, performance of the semiconductor device may be optimized, and integration density of the semiconductor device may be increased.

While the example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a lower structure including a lower bonding layer;
an intermediate structure disposed on the lower structure and including a first intermediate bonding layer bonded to the lower bonding layer and a second intermediate bonding layer opposing the first intermediate bonding layer; and
an upper structure disposed on the intermediate structure and including an upper bonding layer bonded to the second intermediate bonding layer,
wherein the lower structure further includes lower memory cells,
wherein the intermediate structure further includes first peripheral circuits,
wherein the upper structure further includes upper memory cells,
wherein each of the lower bonding layer and the first intermediate bonding layer includes a dielectric material and does not include a bonding metal material,
wherein each of the second intermediate bonding layer and the upper bonding layer includes a bonding dielectric layer including a dielectric material and bonding metal patterns including a bonding metal material,
wherein the bonding dielectric layer of the second intermediate bonding layer is bonded to the bonding dielectric layer of the upper bonding layer, and
wherein the bonding metal patterns of the second intermediate bonding layer are bonded to the bonding metal patterns of the upper bonding layer.

2. The semiconductor device of claim 1, wherein the lower memory cells are arranged in a first direction, a second direction, and a vertical direction intersecting one another,
wherein the upper memory cells are arranged in the first direction, the second direction, and the vertical direction,
wherein the lower structure further includes:
lower word lines connected to the lower memory cells; and
lower local bit lines connected to the lower memory cells, and
wherein the upper structure further includes:
upper word lines connected to the upper memory cells; and
upper local bit lines connected to the upper memory cells.

3. The semiconductor device of claim 2, wherein the upper word lines vertically overlap the lower word lines, and
wherein the upper local bit lines vertically overlap the lower local bit lines.

4. The semiconductor device of claim 2, wherein the lower structure further includes lower gate contact plugs connected to the lower word lines,
wherein the upper structure further includes upper gate contact plugs connected to the upper word lines, and
wherein the upper gate contact plugs vertically overlap the lower gate contact plugs.

5. The semiconductor device of claim 2, wherein the first peripheral circuits include:
word line select circuits connected to the lower word lines and the upper word lines; and
sub-word line drivers connected to the word line select circuits.

6. The semiconductor device of claim 5, wherein each of the word line select circuits includes:
a lower word line select transistor electrically connected to a corresponding lower word line among the lower word lines; and
an upper word line select transistor electrically connected to a corresponding upper word line among the upper word lines.

7. The semiconductor device of claim 6, wherein the upper word line select transistor and the lower word line select transistor are configured to operate in a complementary manner, such that the upper word line select transistor is in an off state when the lower word line select transistor is in an on state, and the upper word line select transistor is in an on state when the lower word line select transistor is in an off state.

8. The semiconductor device of claim 5, wherein the lower structure and the intermediate structure further include first lower routing interconnection structures electrically connecting the lower word lines to the sub-word line drivers, and
wherein the intermediate structure and the upper structure further include first upper routing interconnection structures electrically connecting the upper word lines to the sub-word line drivers.

9. The semiconductor device of claim 8, wherein the intermediate structure further includes an intermediate semiconductor body, and
wherein the first lower routing interconnection structures include:
lower gate contact plugs connected to the lower word lines;
first lower routing interconnections disposed on the lower gate contact plugs and connected to the lower gate contact plugs;
through-conductive patterns penetrating the intermediate semiconductor body and connected to the first lower routing interconnections; and
first intermediate routing interconnections disposed on the intermediate semiconductor body and connected to the through-conductive patterns.

10. The semiconductor device of claim 2, wherein the lower structure further includes lower global bit lines electrically connected to the lower local bit lines,
wherein the upper structure further includes upper global bit lines electrically connected to the upper local bit lines,
wherein each of the lower global bit lines is electrically connected to an N number of lower local bit lines among the lower local bit lines,
wherein each of the upper global bit lines is electrically connected to the N number of upper local bit lines among the upper local bit lines, and
wherein N is a natural number of 2 or more.

11. The semiconductor device of claim 10, wherein the lower global bit lines vertically overlap the upper global bit lines.

12. The semiconductor device of claim 10, wherein the first peripheral circuits further include:
bit line select circuits electrically connected to the lower global bit lines and the upper global bit lines; and
bit line sense amplifiers connected to the bit line select circuits.

13. The semiconductor device of claim 1, wherein the upper structure further includes second peripheral circuits disposed at a level higher than a level of the upper memory cells.

14. A semiconductor device, comprising:
a lower structure including lower word lines, lower local bit lines, and lower memory cells connected to the lower word lines and the lower local bit lines;
an upper structure including upper word lines, upper local bit lines, and upper memory cells connected to the upper word lines and the upper local bit lines; and
an intermediate structure disposed between the lower structure and the upper structure, and
wherein the intermediate structure includes:
word line select circuits electrically connected to the lower word lines and the upper word lines; and
sub-word line drivers electrically connected to the word line select circuits.

15. The semiconductor device of claim 14, wherein each of the word line select circuits includes:
a lower word line select transistor electrically connected to a corresponding lower word line among the lower word lines; and
an upper word line select transistor electrically connected to a corresponding upper word line among the upper word lines.

16. The semiconductor device of claim 14, wherein the intermediate structure further includes:
bit line select circuits electrically connected to the lower local bit lines and the upper local bit lines; and
bit line sense amplifiers electrically connected to the bit line select circuits.

17. The semiconductor device of claim 16, wherein the lower structure further includes lower global bit lines electrically connected to the lower local bit lines,
wherein the upper structure further includes upper global bit lines electrically connected to the upper local bit lines,
wherein each of the lower global bit lines is electrically connected to an N number of lower local bit lines among the lower local bit lines,
wherein each of the upper global bit lines is electrically connected to the N number of upper local bit lines among the upper local bit lines, and
wherein N is a natural number of 2 or more.

18. The semiconductor device of claim 17, wherein a first bit line select circuit among the bit line select circuits is connected to a first bit line sense amplifier among the bit line sense amplifiers,
wherein the first bit line select circuit includes:
a first lower bit line select transistor;
a second lower bit line select transistor;
a first upper bit line select transistor; and
a second upper bit line select transistor,
wherein the first and second lower bit line select transistors are electrically connected to a first lower global bit line and a second lower global bit line among the lower global bit lines, respectively, and
wherein the first and second upper bit line select transistors are electrically connected to a first upper global bit line and a second upper global bit line among the upper global bit lines, respectively.

19. A semiconductor device, comprising:
a lower structure including a lower bonding layer;
an intermediate structure disposed on the lower structure and including a first intermediate bonding layer bonded to the lower bonding layer and a second intermediate bonding layer opposing the first intermediate bonding layer; and
an upper structure disposed on the intermediate structure and including an upper bonding layer bonded to the second intermediate bonding layer,
wherein the lower structure further includes:
lower memory cells arranged in a first direction, a second direction, and a vertical direction intersecting one another;
lower word lines connected to the lower memory cells; and
lower local bit lines connected to the lower memory cells,
wherein the intermediate structure further includes first peripheral circuits,
wherein the upper structure further includes:
upper memory cells arranged in the first direction, the second direction, and the vertical direction;
upper word lines connected to the upper memory cells;
upper local bit lines connected to the upper memory cells; and
second peripheral circuits disposed at a level higher than a level of the upper memory cells,
wherein the first peripheral circuits include:
sub-word line select circuits electrically connected to the lower word lines and the upper word lines; and
sub-word line drivers connected to the sub-word line select circuits.

20. The semiconductor device of claim 19,
wherein the lower structure further includes lower global bit lines electrically connected to the lower local bit lines,
wherein the upper structure further includes upper global bit lines electrically connected to the upper local bit lines,
wherein each of the lower global bit lines is electrically connected to an N number of lower local bit lines among the lower local bit lines,
wherein each of the upper global bit lines is electrically connected to the N number of upper local bit lines among the upper local bit lines, and
wherein N is a natural number of 2 or more,
wherein the intermediate structure further includes:
bit line select circuits electrically connected to the lower local bit lines and the upper local bit lines; and
bit line sense amplifiers electrically connected to the bit line select circuits,
wherein each of the lower bonding layer and the first intermediate bonding layer includes a dielectric material and does not include a bonding metal material,
wherein each of the second intermediate bonding layer and the upper bonding layer includes a bonding dielectric layer including a dielectric material and bonding metal patterns including a bonding metal material,
wherein the bonding dielectric layer of the second intermediate bonding layer is bonded to the bonding dielectric layer of the upper bonding layer, and
wherein the bonding metal patterns of the second intermediate bonding layer are bonded to the bonding metal patterns of the upper bonding layer.
